(19) United States
(12) Patent Application Publication
(10) Pub. No.: US 2016/0079241 A1
(43) Pub. Date: Mar. 17, 2016

(54) INTEGRATED CIRCUIT DEVICE INCLUDING BLOCKING INSULATING LAYER

(71) Applicant: Samsung Electronics Co., Ltd., Suwon-si (KR)

(72) Inventors: Hyun-jo KIM, Seoul (KR); Hyung-jong LEE, Osan-si (KR); Ju-youn KIM, Suwon-si (KR); Jong-mil YOUN, Yongin-si (KR)

(21) Appl. No.: 14/718,034

(22) Filed: May 20, 2015

(30) Foreign Application Priority Data
Sep. 12, 2014 (KR) 10-2014-0121272

(51) Int. Cl. H01L 27/088; H01L 29/423; H01L 29/06

(52) U.S. Cl. CPC H01L 27/0886; H01L 29/0611; H01L 29/4232

(57) ABSTRACT

An integrated circuit device includes an active area, a gate line extending in a direction across the active area and having a gate uppermost surface of a first level, a source/drain regions, an inter-gate insulating film covering opposite sidewalls of the gate line, a blocking insulating film comprising a first part covering the gate uppermost surface and a second part covering the inter-gate insulating film at a level different from the first level, and a contact plug penetrating the blocking insulating film and the inter-gate insulating film and connected to the source/drain regions.

### CROSS-REFERENCE TO RELATED APPLICATIONS

This application claims the benefit of Korean Patent Application No. 10-2014-0121272, filed on Sep. 12, 2014, in the Korean Intellectual Property Office, the disclosure of which is incorporated herein in its entirety by reference.

### BACKGROUND

The present disclosure relates to an integrated circuit device, and more particularly, to an integrated circuit device including a blocking insulating film covering a gate.

Since a feature size of a MOS transistor is reduced, a length of a gate and a length of a channel formed therebelow is also reduced. Accordingly, to improve an operation stability of transistors that are important factors determining performance of integrated circuits, efforts are made to improve characteristics related to an operation speed, a power dissipation, and economical efficiency.

### SUMMARY

Aspects of the inventive concept provide an integrated circuit device having a structure capable of reducing a leakage current through interfaces between membrane materials and preventing an electrical characteristic deterioration due to the leakage current.

According to an aspect of the inventive concept, there is provided an integrated circuit (IC) device including: a fin type active area formed on a substrate; a gate line extending in a direction across the fin type active area on the fin type active area and having a gate uppermost surface at a first level; a pair of source/drain regions formed in the fin type active area at both sides of the gate line; an inter-gate insulating film covering the pair of source/drain regions and opposite sidewalls of the gate line; a blocking insulating film including a first part covering the gate uppermost surface and a second part integrally connected to the first part and covering the inter-gate insulating film at a level that is different from the first level; and a contact plug penetrating the blocking insulating film and the inter-gate insulating film and connected to one of the pair of source/drain regions.

The first part of the blocking insulating film may be spaced apart from the gate uppermost surface, and the first part and the second part of the blocking insulating film may extend in parallel to the substrate at a second level that is farther from the substrate than the first level.

The IC device may further include an insulating margin layer disposed between the gate line and the blocking insulating film and between the inter-gate insulating film and the blocking insulating film and surrounding the contact plug.

The insulating margin layer may include a same material as that of the inter-gate insulating film.

The blocking insulating film may include a top surface extending flat on a same plane from the first part to the second part.

The inter-gate insulating film may include an insulating film uppermost surface at a same level as the first level.

The second part of the blocking insulating film may be spaced apart from the insulating film uppermost surface of the inter-gate insulating film.

The first part of the blocking insulating film may contact the gate uppermost surface, and the second part of the blocking insulating film may include a bottom surface extending at a third level closer to the substrate than the first level.

The inter-gate insulating film may include an insulting film uppermost surface at a fourth level closer to the substrate than the first level.

The second part of the blocking insulating film may contact the insulating uppermost surface of the inter-gate insulating film.

The IC device may further include an insulating spacer covering sidewalls of the gate line, wherein the blocking insulating film may further include a third part covering the sidewalls of the gate line with the insulating spacer between the blocking insulating film and the third part.

According to another aspect of the inventive concept, there is provided an IC device including a gate formed on a substrate and including a gate uppermost surface at a first level; a pair of source/drain regions formed in the substrate at both sides of the gate; an inter-gate insulating film covering the pair of source/drain regions and opposite sidewalls of the gate; a blocking insulating film including a first part covering the gate uppermost surface and a second part integrally connected to the first part and covering the inter-gate insulating film at a level that is different from the first level; and a contact plug penetrating the blocking insulating film and the inter-gate insulating film and connected to one of the pair of source/drain regions.

The first part of the blocking insulating film may be spaced apart from the gate uppermost surface, and the first part and the second part of the blocking insulating film may extend flat on a same plane.

The IC device may further include an insulating margin layer covering the gate and the inter-gate insulating film and formed of a material that is different from that of the blocking insulating film, wherein the insulating margin layer may cover sidewalls of the contact plug between the blocking insulating film and the inter-gate insulating film.

The inter-gate insulating film may include an insulating film uppermost surface at a fourth level that is closer to the substrate than the gate uppermost surface; the first part of the blocking insulating film may contact the gate uppermost surface; and the second part of the blocking insulating film may contact the insulating film uppermost surface.

According to another aspect of the inventive concept, there is provided an IC device including a pair of gates extending in parallel to each other with a first space therebetween on a substrate and each including a gate uppermost surface at a first level; a source/drain region formed in the substrate between the pair of gates; an inter-gate insulating film covering the source/drain region in the first space; a blocking insulating film including a first part covering the pair of gates and a second part covering the inter-gate insulating film at a level that is different from the first level; and a contact plug penetrating the blocking insulating film and the inter-gate insulating film and connected to the source/drain region.

The IC device may further include at least one fin type active area formed in the substrate, wherein the pair of gates may extend across the at least one fin type active area on the at least one fin type active area, and wherein the source/drain region may be formed in the at least one fin type active area.

The pair of gates may be formed of metal, and the blocking insulating film may include a film including silicon and nitrogen.

The IC device may further include an insulating margin layer disposed between the second part of the blocking insulating film and the inter-gate insulating film and formed of a material that is different from that of the blocking insulating film, wherein the second part of the blocking insulating film may be formed at a second level that is farther from the substrate than the first level.

The first part of the blocking insulating film may contact the gate uppermost surface, and the second part of the blocking insulating film may contact the inter-gate insulating film at a third level closer to the substrate than the first level.

### BRIEF DESCRIPTION OF THE DRAWINGS

Exemplary embodiments of the inventive concept will be more clearly understood from the following detailed description taken in conjunction with the accompanying drawings in which:

FIG. 1 is a layout diagram of an integrated circuit device, according to an embodiment of the inventive concept;

FIGS. 2A through 2C are cross-sectional views of integrated circuit devices, taken along a line 2A-2A′, a line 2B-2B′, and a line 2C-2C′ of FIG. 1, respectively, according to embodiments of the inventive concept;

FIG. 3 is a cross-sectional view of an integrated circuit device, according to another embodiment of the inventive concept;

FIG. 4 is a cross-sectional view of an integrated circuit device, according to another embodiment of the inventive concept;

FIG. 5 is a cross-sectional view of an integrated circuit device, according to another embodiment of the inventive concept;

FIGS. 6A through 15C are cross-sectional views for sequentially explaining a method of manufacturing an integrated circuit device, in which FIGS. 6A through 15A, FIGS. 6B through 15B, and FIGS. 6C through 15C are cross-sectional views taken along the line 2A-2A′, the line 2B-2B′, and the line 2C-2C′ of FIG. 1, respectively, according to embodiments of the inventive concept;

FIGS. 16A through 16D are cross-sectional views for sequentially explaining a method of manufacturing an integrated circuit device, according to another embodiment of the inventive concept;

FIGS. 17A through 17F are cross-sectional views for sequentially explaining a method of manufacturing an integrated circuit device, according to another embodiment of the inventive concept;

FIGS. 18A through 18D are cross-sectional views for sequentially explaining a method of manufacturing an integrated circuit device, according to another embodiment of the inventive concept;

FIG. 19 is a plan view of a memory module, according to an embodiment of the inventive concept;

FIG. 20 is a schematic block diagram of a display driving integrated circuit and a display apparatus, according to an embodiment of the inventive concept;

FIG. 21 is a circuit diagram of a CMOS inverter, according to an embodiment of the inventive concept;

FIG. 22 is a circuit diagram of a CMOS SRAM device, according to an embodiment of the inventive concept;

FIG. 23 is a circuit diagram of a CMOS NAND circuit, according to an embodiment of the inventive concept;

FIG. 24 is a block diagram of an electronic system, according to an embodiment of the inventive concept; and

FIG. 25 is a block diagram of an electronic system, according to another embodiment of the inventive concept.

### DETAILED DESCRIPTION

Hereinafter, various aspects of the inventive concept will be described in detail by explaining exemplary embodiments of the invention with reference to the attached drawings. Like reference numerals in the drawings denote like elements, and thus their description will be omitted.

The inventive concept may, however, be embodied in many different forms and should not be construed as limited to the exemplary embodiments set forth herein. In the drawings, lengths and sizes of layers and regions may be exaggerated for clarity.

Also, though terms like ‘first’ and ‘second’ are used to describe various elements, components, regions, layers, and/or portions in various embodiments of the inventive concept, the elements, components, regions, layers, and/or portions should not be limited by these terms. Unless the context indicates otherwise, these terms are only used to distinguish one element, component, region, layer, or portion from another, for example as a naming convention. Thus, a first element, component, region, layer or section discussed below could be termed a second element, component, region, layer or section without departing from the teachings of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “and/or” includes any and all combinations of one or more of the associated listed items. Expressions such as “at least one of,” when preceding a list of elements, modify the entire list of elements and do not modify the individual elements of the list.

When a certain embodiment can be embodied in a different manner, a specified process order may be performed in a different manner than the order described. For example, two processes to be described sequentially may be substantially performed at the same time or may be performed in an order opposite to the order described.

Variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). However, the term “contact,” as used herein refers to direct contact (i.e., touching) unless the context indicates otherwise.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures may have schematic properties, and shapes of regions shown in figures may exemplify specific shapes of regions of elements to which aspects of the invention are not limited.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning

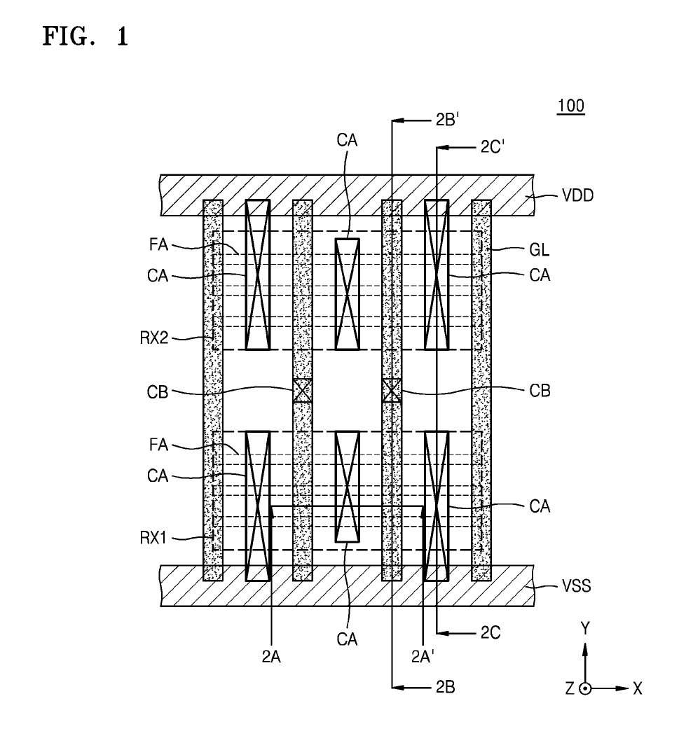

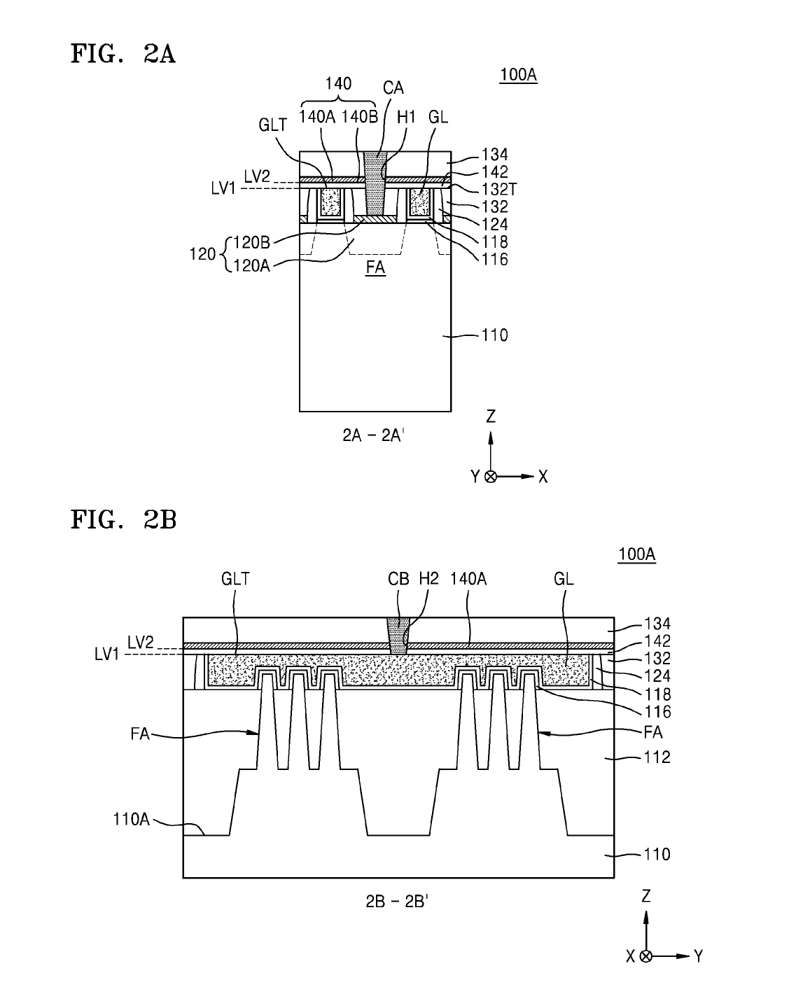

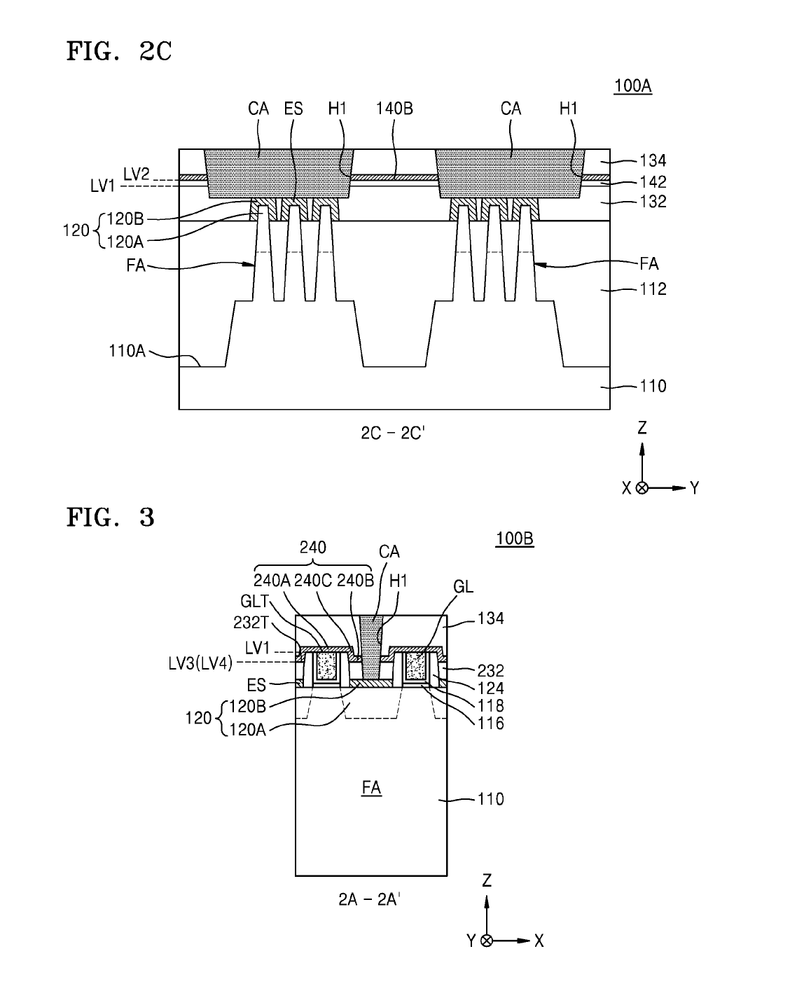

FIG. 1 is a layout diagram of an integrated circuit device 100, according to an embodiment of the inventive concept. FIGS. 2A through 2C are cross-sectional views of exemplary integrated circuit devices having the same layout as that of the integrated circuit device 100 of FIG. 1, taken along a line 2A-2A′, a line 2B-2B′, and a line 2C-2C′ of FIG. 1, respectively, according to embodiments of the inventive concept.

As described herein, an integrated circuit device may form a semiconductor device. As used herein, a semiconductor device may refer to any of the various devices such as shown in FIGS. 1-18C, and may also refer, for example, to two transistors or a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

An electronic device, as used herein, may refer to these semiconductor devices, but may additionally include products that include these devices, such as a memory module, memory card, hard drive including additional components, or a mobile phone, laptop, tablet, desktop, camera, or other consumer electronic device, etc.

Referring to FIGS. 1 through 2C, a substrate 110 including a main surface 110A extending in a horizontal direction (X and Y directions of FIG. 1) includes a first device area RX1 and a second device RX2 in which a plurality of fin type active areas FA protruding from the substrate 110 are formed.

In some embodiments, the substrate 110 may include a semiconductor such as silicon (Si) or germanium (Ge), or a compound semiconductor such as silicon germanium (SiGe), silicon carbide (SiC), gallium arsenide (GaAs), indium arsenide (InAs), or indium phosphide (InP). In other embodiments, the substrate 110 may have a silicon on insulator (SOI) structure. The substrate 110 may include a conductive area, for example, a well doped with impurities or a structure doped with impurities.

The plurality of fin type active areas FA may extend in parallel to each other in one direction (X direction of FIG. 1). A device isolation film 112 is formed between the plurality of fin type active areas FA on the substrate 110. The plurality of fin type active areas FA may protrude from the device isolation film 112 in a fin shape.

A plurality of interface films 116, a plurality of gate insulating films 118, and a plurality of gate lines GL extend in a direction (Y direction of FIG. 1) crossing the plurality of fin type active areas FA on the substrate 110. The plurality of gate insulating films 118 and the plurality of gate lines GL may extend covering a top surface and both side walls of each of the plurality of fin type active areas FA and a top surface of the device isolation film 112. A plurality of MOS transistors are formed along the plurality of gate lines GL. Each of the plurality of MOS transistors may be configured as a MOS transistor of a 3-dimensional structure in which a channel is formed in the top surface and both (e.g., opposite) side walls of each of the plurality of fin type active areas FA.

Both side walls of each of the plurality of interface films 116, the plurality of gate insulating films 118, and the plurality of gate lines GL are covered by an insulating spacer 124.

Each of the plurality of interface films 116 is obtained by oxidizing an exposed surface of each of the plurality of fin type active areas FA and may prevent a defective interface between the plurality of fin type active areas FA and the plurality of gate insulating films 118. In some embodiments, the plurality of interface films 116 may be formed of a low dielectric material layer having a dielectric permittivity equal to or lower than 9, for example, a silicon oxide film, a silicon oxynitride film, or a combination of these. In some other embodiments, the plurality of interface films 116 may be formed of silicate or a combination of silicate and the materials mentioned above.

The plurality of gate insulating films 118 may be formed of the silicon oxide film, a high dielectric film, or a combination of these. The high dielectric film may be formed of a material having a greater dielectric constant than that of the silicon oxide film. For example, the plurality of gate insulating films 118 may have dielectric constants between about 10 and about 25. The high dielectric film may be formed of a material selected from the group consisting of hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate but the materials of the high dielectric film are not limited thereto. The plurality of gate insulating films 118 may be formed, for example, through an atomic layer deposition (ALD) process, a chemical vapor deposition (CVD) process, or a physical vapor deposition (PVD) process.

The plurality of gate lines GL covers the top surface and both surfaces of each of the plurality of fin type active areas FA on the gate insulating film 118 to extend in a direction crossing the plurality of fin type active areas FA.

The plurality of gate lines GL includes a gate uppermost surface GLT extending flat at a first level LV1 on the substrate 110.

In some embodiments, the gate lines GL may have a structure in which a metal nitride layer, a metal layer, a conductive capping layer, and a gap-fill metal film are sequentially stacked.

The metal nitride layer and the metal layer may include at least one metal selected from the group consisting of Ti, Ta, W, Ru, Nb, Mo, and Hf.

The metal nitride layer and the metal layer may be formed through the ALD process, a metal organic ALD (MOALD) process, or a metal organic CVD (MOCVD) process.

The conductive capping layer may serve as a protection film preventing a surface of the metal layer from being oxidized. The conductive capping layer may serve as a wetting layer for facilitating deposition when another conductive layer is deposited on the metal layer. The conductive capping layer may be formed of, for example, TiN, TaN, or a combination of these, but is not limited thereto.

The gap-fill metal film may fill spaces between the plurality of fin type active areas FA to extend on the conductive capping layer. The gap-fill metal film may be formed as a W film. The gap-fill metal film may be formed through the ALD process, the CVD process, or the PDV process. The gap-fill metal film may fill a recess space formed by a step unit of a top surface of the conductive capping layer in the spaces between the plurality of fin type active areas FA without a void.

A plurality of conductive contact plugs CA and CB are formed on the plurality of fin type active areas FA. The plurality of conductive contact plugs CA and CB includes the plurality of first contact plugs CA connected to a plurality of source/drain regions 120 and the plurality of second contact plugs CB connected to the plurality of gate liens GL among the plurality of fin type active areas FA. Each of the plurality of source/drain regions 120 may include a first source/drain region 120A formed in partial regions of both sides of the gate lines GL and a second source/drain region 120B disposed in the first source/drain region 120A and formed in a semiconductor layer ES epitaxially grown from the plurality of fin type active areas FA, among the plurality of fin type active areas FA.

The plurality of conductive contact plugs CA and CB may be mutually insulated by an inter-gate insulating film 132 filling the spaces between the plurality of gate lines GL and an interlayer insulating film 134 covering the plurality of fin type active areas FA and gate lines GL.

The inter-gate insulating film 132 may be formed to cover both (e.g., opposite) side walls of the source/drain regions 120 and gate lines GL. The inter-gate insulating film 132 and the interlayer insulating film 134 may be formed as silicon oxide films but are not limited thereto. The inter-gate insulating film 132 may include an insulating film uppermost surface 132T at the same level as the first level LV1.

A blocking insulating film 140 is formed on the gate lines GL and the inter-gate insulating film 132. The blocking insulating film 140 prevents undesired impurities such as oxygen from penetrating into the plurality of gate lines GL, thereby preventing a threshold voltage from being undesirably changed in the gate lines GL or the gate lines GL and the first contact plugs CA from being short-circuited. The blocking insulating film 140 may be formed to maintain the threshold voltage constant in the gate lines GL, and an electrical characteristic deterioration of a transistor including the gate lines GL may be prevented.

The blocking insulating film 140 includes a first part 140A covering the gate uppermost surface GLT and a second part 140B integrally connected to the first part 140A and covering the inter-gate insulating film 132 at a different level from the first level LV1.

The second part 140B of the blocking insulating film 140 is spaced apart from the insulating film uppermost surface 132T of the inter-gate insulating film 132.

In FIGS. 2A through 2C, the first part 140A and the second part 140B of the blocking insulating film 140 extend in parallel to the substrate 110 at a second level LV2 that is farther from the substrate 110 than the first level LV1. The blocking insulating film 140 may include a bottom surface extending in parallel from the first part 140A to the second part 140B at the second part LV2.

An insulating margin layer 142 is disposed between the gate lines GL and the blocking insulating film 140 and between the inter-gate insulating film 132 and the blocking insulating film 140.

The first contact plugs CA may penetrate into the blocking insulating film 140, the insulating margin layer 142, and the inter-gate insulating film 132 to connect to the source/drain regions 120. The blocking insulating film 140 and the insulating margin layer 142 may have a shape surrounding the first contact plugs CA.

In some embodiments, the blocking insulating film 140 may have a thickness in the range of about 20˜about 50 Å. The insulating margin layer 142 may have a thickness in the range of about 30˜about 100 Å.

In some embodiments, the insulating margin layer 142 may be formed of a material different from a material of the blocking insulating film 140. The insulating margin layer 142 may be formed of a same material as a material of the inter-gate insulating film 132. In some embodiments, the blocking insulating film 140 may be formed as a film including silicon and nitrogen. For example, the blocking insulating film 140 may be formed as a silicon nitride (Si₃N₄) film, a silicon oxynitride (SiON) film, a carbon containing silicon oxynitride (SiCON) film, or a combination of these. In some embodiments, the insulating margin layer 142 and the inter-gate insulating film 132 may be formed as silicon oxide films.

The interlayer insulating film 134 may be formed on the blocking insulating film 140. The interlayer insulating film 134 may be formed as the silicon oxide film but is not limited thereto.

In the integrated circuit devices 100 and 100A, a power line VDD may be connected to the fin type active areas FA in the first device area RX1, and a ground line VSS may be connected to the fin type active areas FA in the second device area RX2.

The power line VDD and the ground line VSS may be formed at a same level as a wiring layer formed on the interlayer insulating film 134 but the inventive concept is not limited.

The contact plugs CA and CB, the power line VDD, and the ground line VSS may have a stack structure of a barrier film and a wiring conductive layer. The barrier film may be formed of TiN, TaN, or a combination of these. The wiring conductive layer may be formed of W, Cu, alloys of these, or a combination of these. The contact plugs CA and CB, the power line VDD, and the ground line VSS may be formed by using the CVD process, the ALD process, or an electroplating process.

In some embodiments, the inter-gate insulating film 132 and the interlayer insulating film 134 may be formed of different materials. For example, the interlayer insulating film 134 may be formed as one film selected from a tetra ethyl ortho silicate (TEOS) film and a ultra low k (ULK) film having a ultra low dielectric constant K in the range of about 2.2˜about 2.4, for example, an SiOC film and an SiCOH film.

In the integrated circuit device 100A described with reference to FIGS. 2A through 2C, the second level LV2 at which the bottom surface of the blocking insulating film 140, i.e., an interface between the blocking insulating film 140 and the insulating margin layer 142, is disposed on the inter-gate insulating film 132 may be higher than the first level LV1 at which the gate uppermost surface GLT of the gate lines GL is disposed. Thus, a path from a part of the bottom surface of the blocking insulating film 140 contacting the first contact plugs CA to the gate lines GL along the bottom surface of the blocking insulating film 140 may be increased.

In an exemplary process, when an etching process for forming a first contact hole H1 (see FIG. 2A) used for forming the first contact plug CA is performed, an inner wall of the first contact hole H1 may be closer to the gate line GL than a location according to a design. In particular, when a material of the blocking insulating film 140 is different from materials of the interlayer insulating film 134 and the inter-gate insulting film 132, since a width of the first contact hole H1 is greater than a width according to the design around the blocking insulating film 140, the inner wall of the first contact hole H1 may be closer to the gate line GL. In this regard, unlike in a comparative case where the bottom surface of the blocking insulating film 140, i.e., the interface between the blocking insulating film 140 and the insulating margin layer 142, disposed on the inter-gate insulating film 132 is formed at a same level as the first level LV1 at which the gate uppermost surface GLT of the gate lines GL is disposed, since the bottom surface of the blocking insulating film 140 is disposed at the second level LV2 higher than the first level LV1 at which the gate uppermost surface GLT of the gate lines GL is disposed as shown in FIGS. 2A through 2C, a leakage current path along an interface between the bottom surface of the blocking insulating film 140 and the insulating margin layer 142 disposed thereunder may be increased between the gate line GL and the first contact plug CA, thereby preventing an electrical characteristic of the integrated circuit device 100A from deteriorating.

FIG. 3 is a cross-sectional view of an integrated circuit device 100B, according to another embodiment of the inventive concept. The integrated circuit device 100B of FIG. 3 may have a same layout as that of the integrated circuit device 100 of FIG. 1. The integrated circuit device 100B of FIG. 3 corresponds to the integrated circuit device 100 taken along the 2A-2A′ of FIG. 1, and has a generally same configuration as that of the integrated circuit device 100A of FIG. 2A, except that the integrated circuit device 100B includes a blocking insulating film 240 instead of the blocking insulating film 140 of FIG. 2A and an inter-gate insulating film 232 instead of the inter-gate insulating film 132. The same reference numerals between FIG. 3 and FIGS. 1 through 2C denote the same members, and thus detailed descriptions thereof are omitted here.

Referring to FIG. 3, the integrated circuit device 100B includes the blocking insulating film 240 including a first part 240A covering the gate line GL and a second part 240B integrally connected to the first part 240A and covering the inter-gate insulating film 232.

The blocking insulating film 240 may further include a third part 240C covering side walls of the gate line GL with an insulating spacer 124 covering the side walls of the gate line GL between the blocking insulating film 240 and the third part 240C.

The first part 240A of the blocking insulating film 240 may contact the gate uppermost surface GLT of the gate line GL and extend at the first level LV1 on the substrate 110. The second part 240B may have a bottom surface extending at a third level LV3 closer to the substrate 110 than the first level LV1. The third part 240C of the blocking insulating film 240 may be integrally connected to the first part 240A and the second part 240B between the first part 240A and the second part 240B, and may be formed spaced apart from the first contact plug CA to cover side walls of the insulating spacer 124.

The inter-gate insulating film 232 filling spaces between the plurality of gate lines GL has an insulating film uppermost surface 232T extending at a fourth level LV4 closer to the substrate 110 than the first level LV1 at which the gate uppermost surface GLT of the gate line GL is disposed.

The second part 240B of the blocking insulating film 240 may contact the insulating film uppermost surface 232T of the inter-gate insulating film 232. Accordingly, the third level LV3 at which the bottom surface of the blocking insulating film 240 extends and the fourth level LV4 at which the insulating film uppermost surface 232T of the inter-gate insulating film 232 extends may be on an approximately same level.

The first contact plugs CA may penetrate into the interlayer insulating film 134, the blocking insulating film 240, and the inter-gate insulating film 232 to connect to the source/drain regions 120.

The blocking insulating film 240 formed on the gate line GL and the inter-gate insulating film 232 may prevent undesired impurities such as oxygen from penetrating into the plurality of gate lines GL, and prevent the gate lines GL and the first contact plugs CA from being short-circuited. The blocking insulating film 240 may be formed to maintain a threshold voltage constant in the gate lines GL, and an electrical characteristic deterioration of a transistor including the gate lines GL may be prevented.

In the integrated circuit device 100B described with reference to FIG. 3, the third level LV3 at which a bottom surface of the blocking insulating film 240 is disposed on the inter-gate insulating film 232 may be lower than the first level LV1 at which the gate uppermost surface GLT of the gate lines GL is disposed. Thus, a path from a part of the bottom surface of the blocking insulating film 240 contacting the first contact plugs CA to the gate lines GL along the bottom surface of the blocking insulating film 240 may be increased. Thus, a leakage current path along an interface between the bottom surface of the blocking insulating film 240 and the inter-gate insulating film 232 may be increased between the gate line GL and the first contact plug CA, thereby preventing an electrical characteristic of the integrated circuit device 100B from deteriorating.

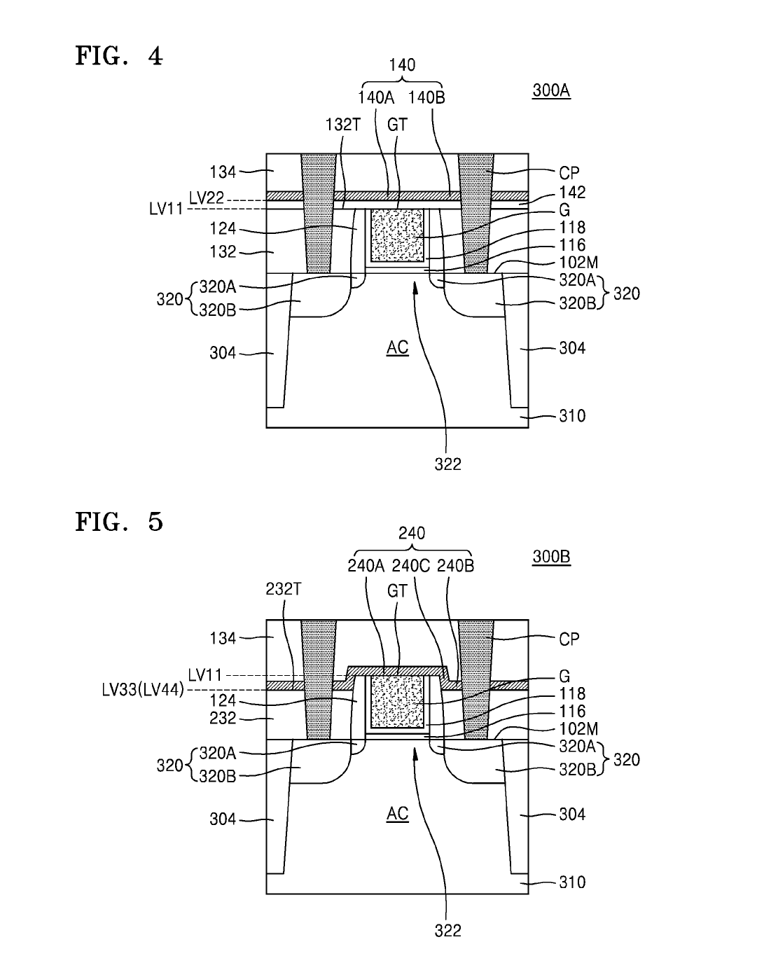

FIG. 4 is a cross-sectional view of an integrated circuit device 300A, according to another embodiment of the inventive concept. The integrated circuit device 300A of FIG. 4 includes a planar type MOS transistor implemented on a bulk substrate 310. The same reference numerals between FIG. 4 and FIGS. 1 through 3 denote the same members, and thus detailed descriptions thereof are omitted here.

Referring to FIG. 4, an active area AC is defined by a device isolation film 304 in the substrate 310. The active area AC includes a pair of source/drain regions 320 and a channel area 322 extending between the pair of source/drain regions 320.

The substrate 310 may include silicon (Si), for example, crystalline Si, polycrystalline Si, or amorphous Si. In some embodiments, the substrate 310 may include a semiconductor such as germanium (Ge), or a compound semiconductor such as silicon germanium (SiGe), silicon carbide (SiC), gallium arsenide (GaAs), indium arsenide (InAs), or indium phosphide (InP).

A gate G covering the active area AC is formed between the pair of source/drain regions 320 on the substrate 310.

Each of the pair of source/drain regions 320 includes a source/drain extension region 320A having a relatively low impurity doping concentration and a deep source/drain region 320B having an impurity doping concentration higher than that of the source/drain extension region 320A.

The gate G includes a gate uppermost surface GT extending flat at a first level LV11 on the substrate 310. The gate G may have a structure in which a metal nitride layer, a metal layer, a conductive capping layer, and a gap-fill metal film are sequentially stacked. Configurations of the metal nitride layer, the metal layer, the conductive capping layer, and the gap-fill metal film are in detail described with respect to the gate line GL of FIGS. 2A through 2C.

In some embodiments, the gate G may be formed of doped polysilicon, metal, conductive metal nitride, metal silicide, alloy, or a combination of these. For example, the gate G may include at least one metal selected from Al, Ti, Ta, W, Ru, Nb, Mo, or Hf or a nitride of one of these.

A conductive contact plug CP may be connected to each of the pair of source/drain regions 320.

The contact plug CP may be insulated by the inter-gate insulating film 132 covering both sidewalls of the gate G and the interlayer insulating film 134 covering the inter-gate insulating film 132 and the gate G.

The inter-gate insulating film 132 may be formed to cover top surfaces of the source/drain regions 120 and both sidewalls of the gate G. The inter-gate insulating film 132 may include the insulating film uppermost surface 132T at a same level as the first level LV11.

The insulating margin layer 142 and the blocking insulating film 140 are sequentially formed on the gate G and the inter-gate insulating film 132.

The blocking insulating film 140 includes the first part 140A covering the gate uppermost surface GT and the second part 140B integrally connected to the first part 140A and covering the inter-gate insulating film 132 at a different level from the first level LV1.

The second part 140B of the blocking insulating film 140 is spaced apart from the insulating film uppermost surface 132T of the inter-gate insulating film 132.s

The first part 140A and the second part 140B of the blocking insulating film 140 of FIG. 4 extend in parallel to the substrate 310 at a second level LV22 farther away from the substrate 410 than the first level LV11. The blocking insulating film 140 may include a bottom surface extending flat on a same plane of the second level LV22 from the first part 140A to the second part 140B.

The insulating margin layer 142 is disposed between the gate G and the blocking insulating film 140 and between the inter-gate insulating film 132 and the blocking insulating film 140.

The contact plug CP may penetrate through the interlayer insulating film 134, the blocking insulating film 140, the insulating margin layer 142, and the inter-gate insulating film 132 to connect to the source/drain regions 320. The blocking insulating film 140 and the insulating margin layer 142 may have a shape surrounding the contact plug CP.

In the integrated circuit device 300A described with reference to FIG. 4, the blocking insulating film 140 is formed on the gate G and the inter-gate insulating film 232, which may prevent undesired impurities such as oxygen from penetrating into the plurality of gates G, and prevent the gate G and the contact plug CP from being short-circuited. The blocking insulating film 140 may be formed to maintain a threshold voltage constant in the gate G, and an electrical characteristic deterioration of a transistor including the gate G may be prevented.

In the integrated circuit device 300A described with reference to FIG. 4, a bottom surface of the blocking insulating film 140 is disposed the second level LV22 higher than the first level LV11 at which the gate uppermost surface GT of the gate G is disposed, and thus, a leakage current path along an interface between the bottom surface of the blocking insulating film 140 and the insulating margin layer 142 disposed thereunder may be increased between the gate G and the contact plug CP, thereby preventing an electrical characteristic of the integrated circuit device 300A from deteriorating.

FIG. 5 is a cross-sectional view of an integrated circuit device 300B, according to another embodiment of the inventive concept. The integrated circuit device 300B of FIG. 5 includes a planar type MOS transistor implemented on the bulk substrate 310 similarly to the integrated circuit device 300A of FIG. 4. The integrated circuit device 300B of FIG. 5 has a generally same configuration as that of the integrated circuit device 300A of FIG. 4, except that the integrated circuit device 300B includes the blocking insulating film 240 instead of the blocking insulating film 140 of FIG. 4 and the inter-gate insulating film 232 instead of the inter-gate insulating film 132. The same reference numerals between FIG. 5 and FIGS. 1 through 4 denote the same members, and thus detailed descriptions thereof are omitted here.

Referring to FIG. 5, the integrated circuit device 300B includes the blocking insulating film 240 including the first part 240A covering the gate G and the second part 240B integrally connected to the first part 240A and covering the inter-gate insulating film 232.

The blocking insulating film 240 may further include the third part 240C covering side walls of the gate G with the insulating spacer 124 covering the side walls of the gate G between the blocking insulating film 240 and the third part 240C.

The first part 240A of the blocking insulating film 240 may contact the gate uppermost surface GT and extend at the first level LV11 on the substrate 310. The second part 240B may have a bottom surface extending at a third level LV33 closer to the substrate 310 than the first level LV11. The third part 240C of the blocking insulating film 240 may be integrally connected to the first part 240A and the second part 240B between the first part 240A and the second part 240B, and may be formed to cover side walls of the insulating spacer 124 at a position spaced apart from the contact plug CP.

The inter-gate insulating film 232 filling spaces both sides of the gate G has the insulating film uppermost surface 232T extending at a fourth level LV44 closer to the substrate 310 than the first level LV11 at which the gate uppermost surface GT of the gate G is disposed.

The second part 240B of the blocking insulating film 240 may contact the insulating film uppermost surface 232T of the inter-gate insulating film 232. Accordingly, the third level LV33 at which the bottom surface of the blocking insulating film 240 extends and the fourth level LV44 at which the insulating film uppermost surface 232T of the inter-gate insulating film 232 extends may be on a same level.

The contact plug CP may penetrate through the interlayer insulating film 134, the blocking insulating film 240, and the inter-gate insulating film 232 to connect to the source/drain regions 320.

The blocking insulating film 240 formed on the gate G and the inter-gate insulating film 232 may prevent undesired impurities such as oxygen from penetrating into the gate G, and prevent the gate G and the contact plug CP from being short-circuited. The blocking insulating film 240 may be formed to maintain a threshold voltage constant in the gate G, and an electrical characteristic deterioration of a transistor including the gate G may be prevented.

In the integrated circuit device 300B described with reference to FIG. 5, the third level LV33 at which a bottom surface of the blocking insulating film 240 is disposed on the inter-gate insulating film 232 may be lower than the first level LV11 at which the gate uppermost surface GT of the gate G is disposed. Thus, a path from a part of the bottom surface of the blocking insulating film 240 contacting the contact plug CP to the gate G along the bottom surface of the blocking insulating film 240 may be increased. Thus, a leakage current path via an interface between the bottom surface of the blocking insulating film 240 and the inter-gate insulating film 232 may be increased between the gate G and the contact plug CP, thereby preventing an electrical characteristic of the integrated circuit device 300B from deteriorating.

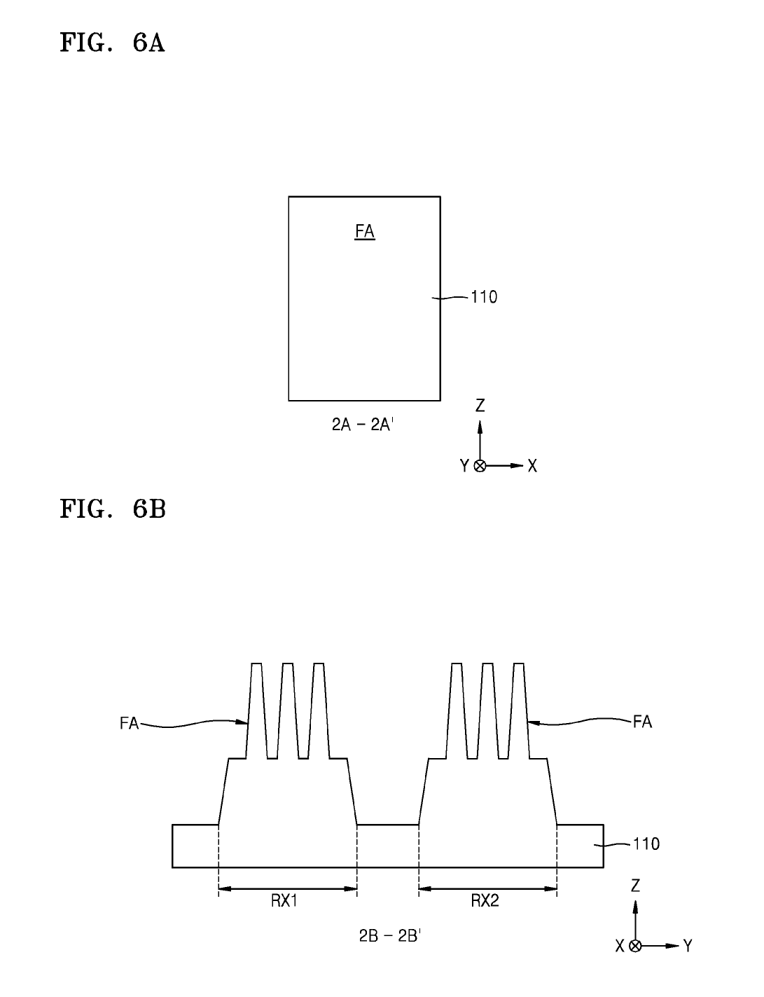

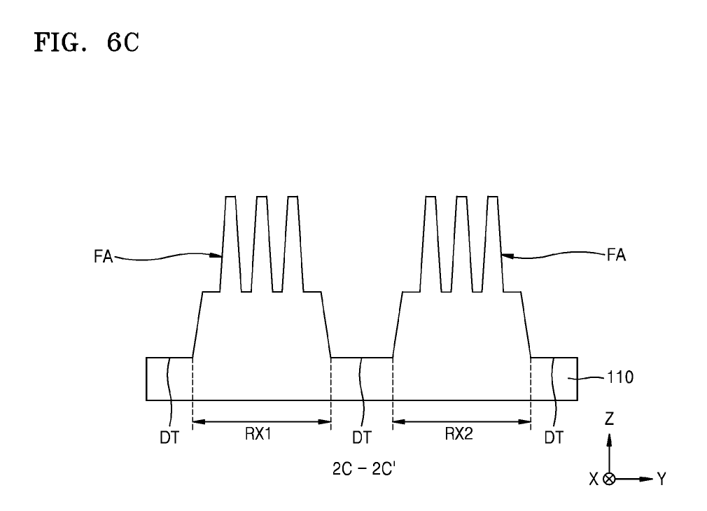

FIGS. 6A through 15C are cross-sectional views for sequentially explaining a method of manufacturing the integrated circuit device 100A, in which FIGS. 6A through 15A, FIGS. 6B through 15B, and FIGS. 6C through 15C are cross-sectional views taken along the line 2A-2A′, the line 2B-2B′, and the line 2C-2C′ of FIG. 1, respectively, according to embodiments of the inventive concept. The method of manufacturing the integrated circuit device 100A will be described with reference to FIGS. 6A through 15C.

Referring to FIGS. 6A through 6C, the substrate 110 including a predetermined MOS area is prepared. A partial area of the substrate 110 is etched to protrude upward from the substrate 110, form the plurality of fin type active area FA extending in a direction, for example, in an X direction in FIGS. 6A through 6C, and form a deep trench DT defining the first device area RX1 and the second device area RX2 including the plurality of fin type active areas FA.

In some embodiments, one of the first device area RX1 and the second device area RX2 may be an area for forming an NMOS transistor and the other one may be an area for forming a PMOS transistor but are not limited thereto. For example, the first device area RX1 and the second device area RX2 may be areas for forming MOS transistors of a same channel type, that is, NMOS transistors or PMOS transistors.

The plurality of fin type active areas FA may include P type or N type impurity diffusion areas (not shown) according to a channel type of an MOS transistor that is to be formed in the fin type active areas FA.

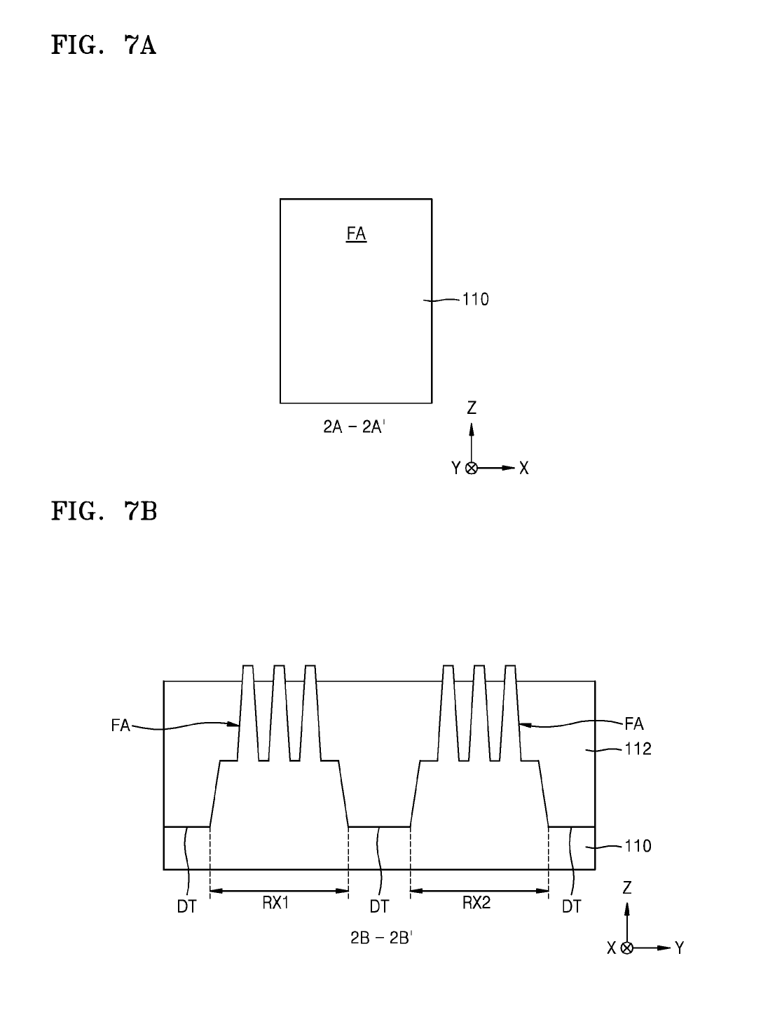

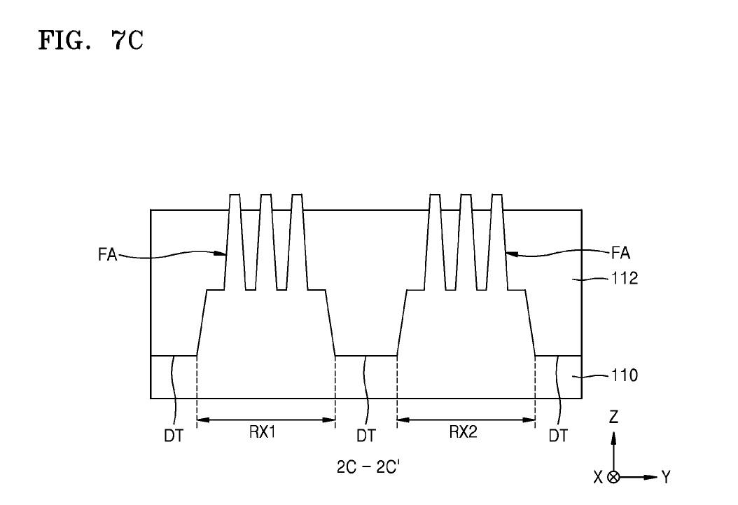

Referring to FIGS. 7A through 7C, an insulting film filling the deep trench DT and covering the plurality of fin type active areas FA is formed, and then etch-backed to form the device isolation film 112. The plurality of fin type active areas FA are exposed to protrude upward from the device isolation film 112.

The device isolation film 112 may be formed as a silicon oxide film, a silicon nitride film, a silicon oxynitride film, or a combination of these. The plurality of device isolation films 112 may include an insulating liner (not shown) formed as a thermal oxide film and a burying insulating film (not shown) burying the deep trench DT on the insulating liner.

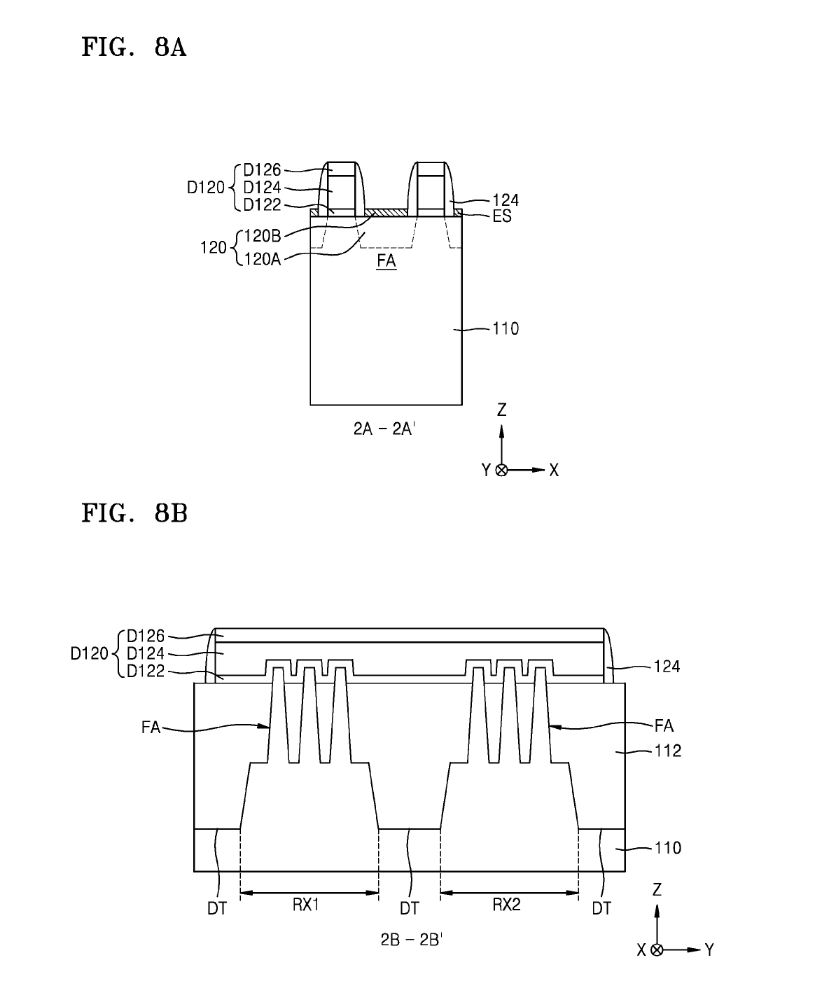

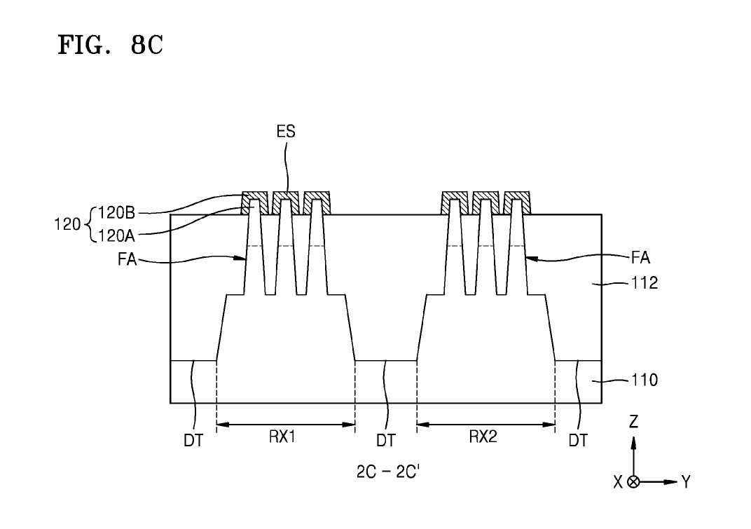

Referring to FIGS. 8A through 8C, a plurality of dummy gate structure D120 extending across the plurality of fin type active areas FA are formed on the plurality of fin type active areas FA.

Each of the plurality of dummy gate structures D120 may include a dummy gate insulating film D122, a dummy gate electrode D124, and a dummy gate capping layer D126 that are sequentially stacked on the fin type active area FA. In some embodiments, the dummy gate insulting film D122 may include silicon oxide. The dummy gate electrode D124 may include polysilicon. The dummy gate capping layer D126 may include at least one of silicon oxide, silicon nitride, and silicon oxynitride.

Thereafter, the insulating spacer 124 is formed in both sidewalls of the dummy gate structure D120. The insulating spacer 124 may be formed of silicon nitride, silicon oxynitride, or a combination of these.

Thereafter, the semiconductor layer ES is formed on the plurality of fin type active areas FA exposed at both sides of the dummy gate structure D120 through an epitaxial growth process. The first source/drain region 120A and the second source/drain region 120B are formed in partial areas of the plurality of fin type active areas FA and the semiconductor layer ES formed on the partial areas.

The first source/drain region 120A and the second source/drain region 120B may have elevated shapes of source/drain regions. A top surface of the second source/drain region 120B may be a higher level than that of a top surface of the fin type active area FA.

In some embodiments, the first source/drain region 120A and the second source/drain region 120B are not limited to cross-sectional shapes as shown in FIG. 8C. For example, the first source/drain region 120A and the second source/drain region 120B may have polygonal shapes such as rectangular, pentagonal, or hexagonal shapes, circular shapes, or oval shapes taken along a plane Y-Z.

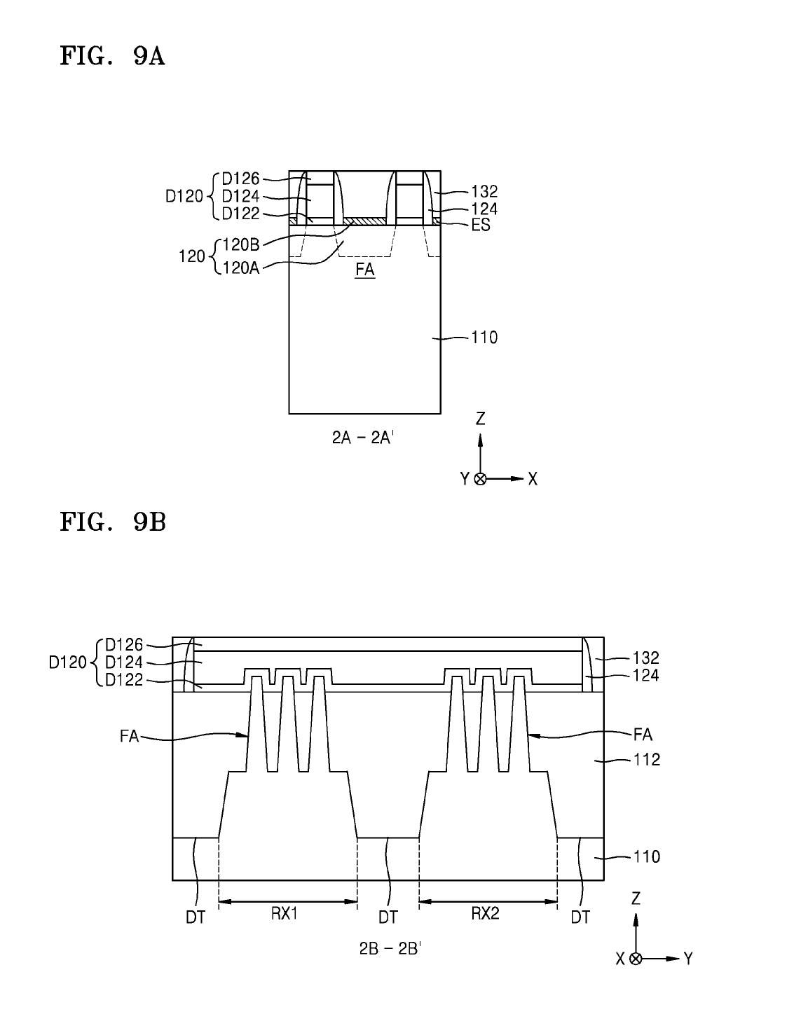

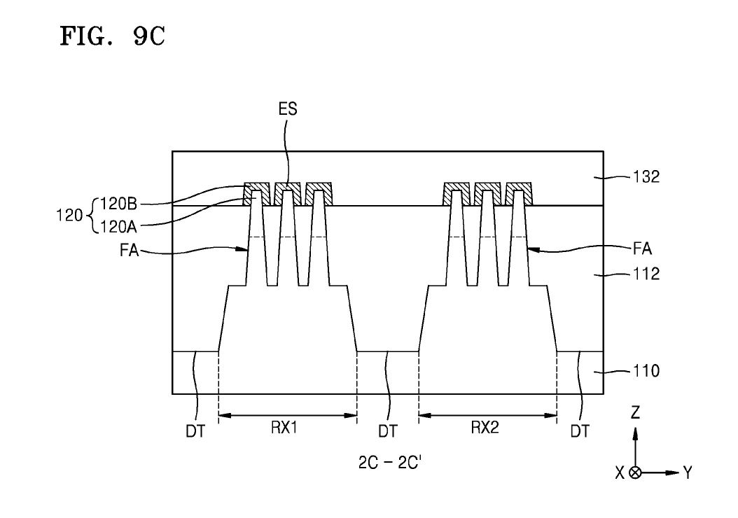

Referring to FIGS. 9A through 9C, the inter-gate insulating film 132 covering the first source/drain region 120A and the second source/drain region 120B and the plurality of dummy gate structures D120 and the insulating spacer 124 is formed.

The inter-gate insulating film 132 having a flattened top surface may be formed by forming an insulating film having a thickness enough to cover the first source/drain region 120A and the second source/drain region 120B and the plurality of dummy gate structures D120 and the insulating spacer 124, and flattening a resultant obtained by forming the insulating film is flattened such that the plurality of dummy gate structures D120 are exposed.

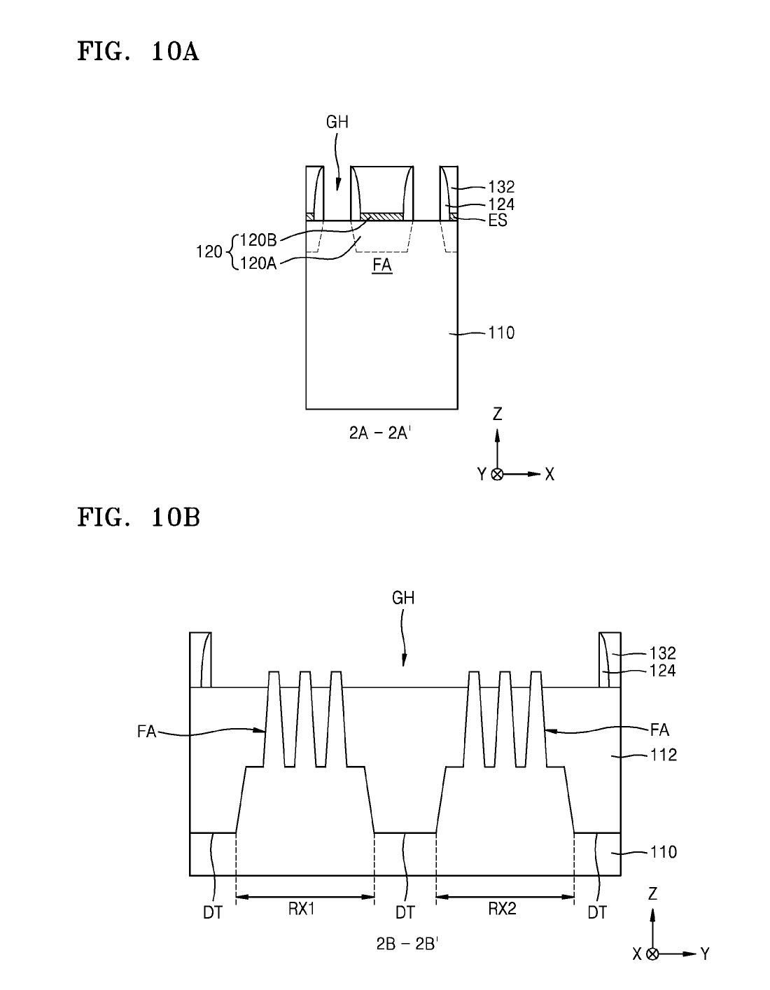

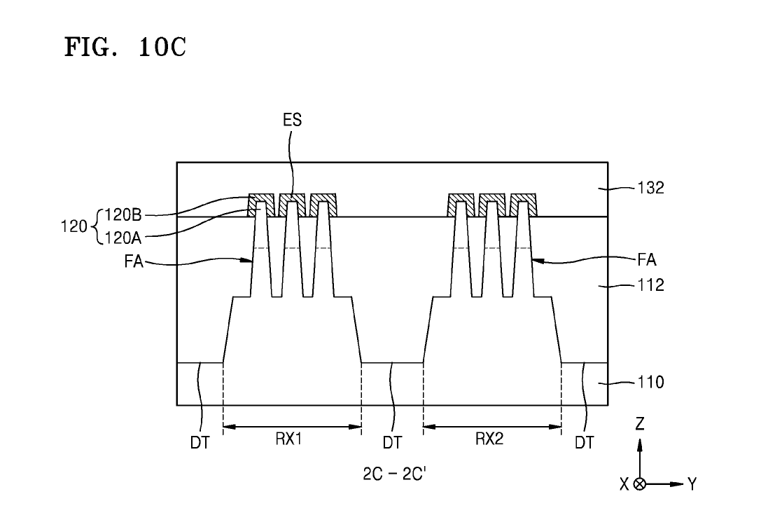

Referring to FIGS. 10A through 10C, a plurality of gate holes GH are formed by removing the plurality of dummy gate structures D120 exposed through the inter-gate insulating film 132.

The insulating spacer 124 and the fin type active area FA may be exposed through the plurality of gate holes GH.

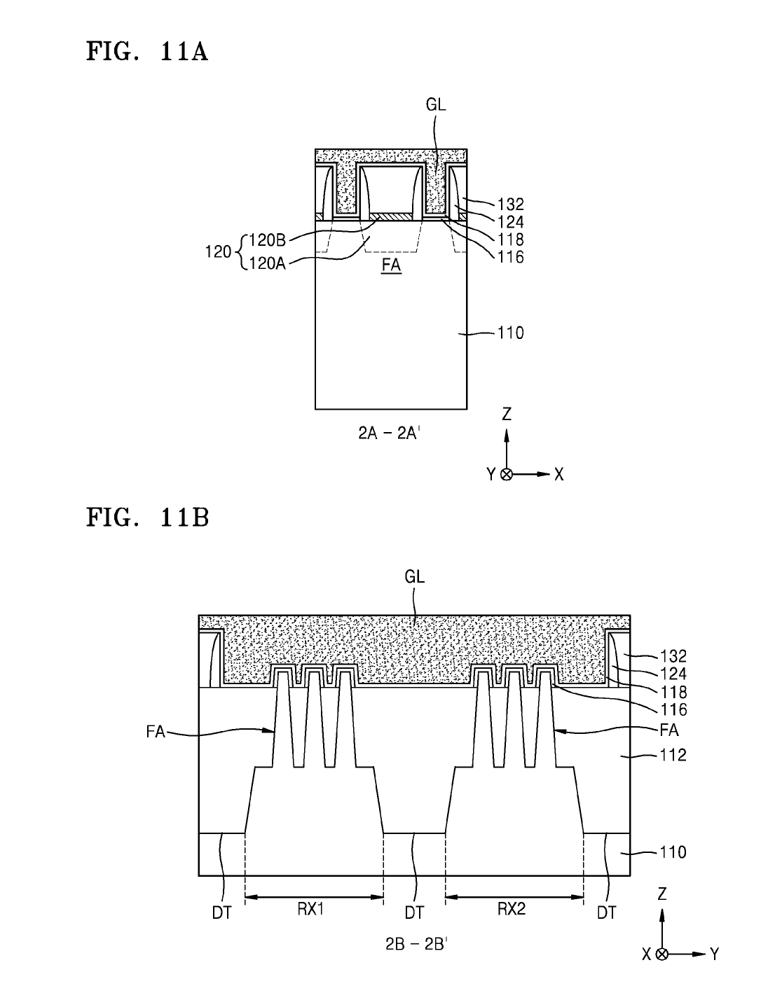

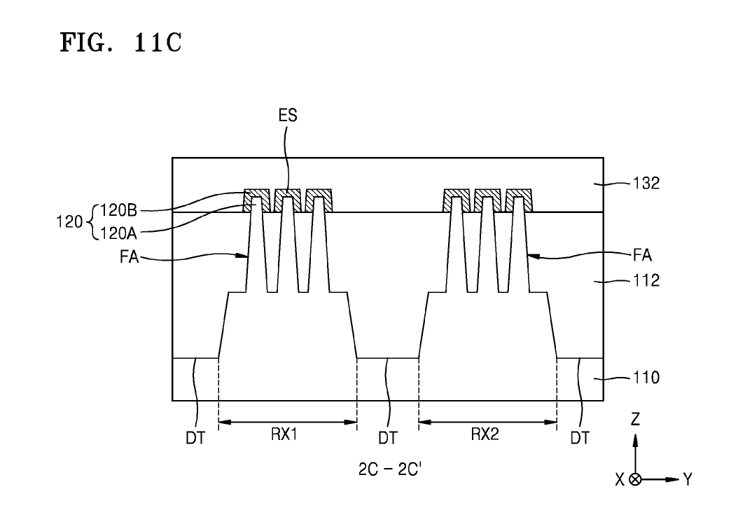

Referring to FIGS. 11A through 11C, the plurality of interface films 116, the plurality of gate insulating films 118, and the plurality of gate lines GL are sequentially formed in the plurality of gate holes GH (see FIGS. 10A and 10B).

A process of forming the plurality of interface films 116 may include a process of oxidizing a part of the fin type active area FA exposed in the plurality of gate holes GH. The plurality of interface films 116 may prevent an interface defect between the plurality of gate insulating films 118 formed thereon and the fin type active area FA formed therebelow. In some embodiments, the plurality of interface films 116 may be formed of silicon oxide film, a silicon oxynitide film, a silicate film, or a combination of these.

The plurality of gate insulating films 118 may be formed of silicon oxide film, a high dielectric film, or a combination of these. The high dielectric film may be formed of a material having a higher dielectric constant than that of the silicon oxide. For example, the gate insulating film 118 may have a dielectric constant in the range of about 10 and about 25.

The plurality of gate lines GL may have a structure in which a metal nitride layer, a metal layer, a conductive capping layer, and a gap-fill metal film are sequentially stacked.

The metal nitride layer and the metal layer may include at least one metal selected from the group consisting of Ti, Ta, W, Ru, Nb, Mo, and Hf.

The metal nitride layer and the metal layer may be formed through the ALD process, a MOALD process, or a MOCVD process.

The conductive capping layer may serve as a protection film preventing a surface of the metal layer from being oxidized. The conductive capping layer may serve as a wetting layer for facilitating deposition when another conductive layer is deposited on the metal layer. The conductive capping layer may be formed of, for example, TiN, TaN, or a combination of these, but is not limited thereto.

The gap-fill metal film may fill spaces between the plurality of fin type active areas FA to extend on the conductive capping layer. The gap-fill metal film may be formed as a W film. The gap-fill metal film may be formed through the ALD process, the CVD process, or the PVD process. The gap-fill metal film may fill a recess space formed by a step unit of a top surface of the conductive capping layer in the spaces between the plurality of fin type active areas FA without a void.

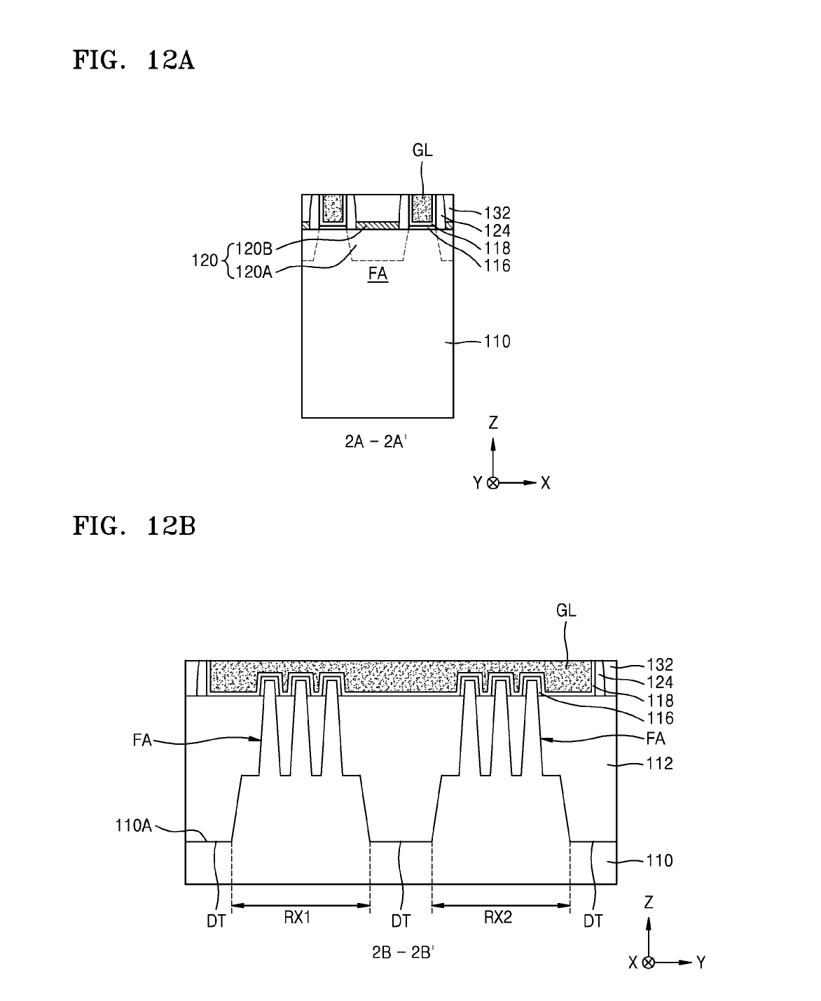

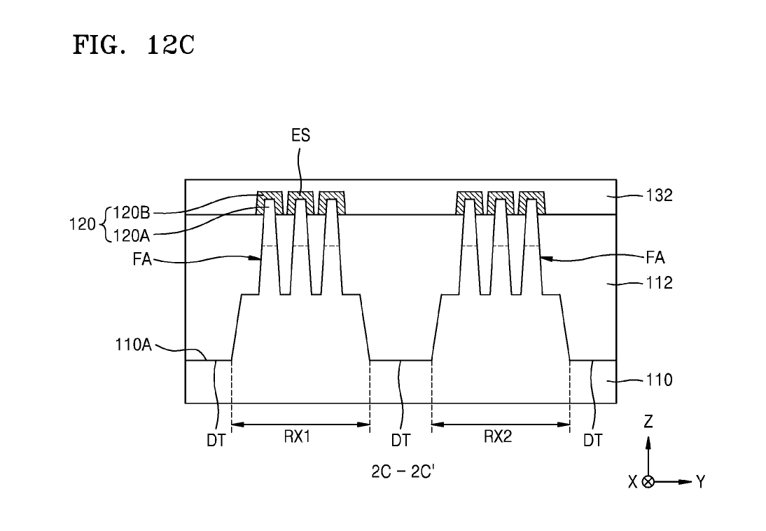

Referring to FIGS. 12A through 12C, a flattening process is performed on a resultant of FIGS. 11A through 11C such that the plurality of gate lines GL and the plurality of gate insulating films 118 may remain only in the plurality of gate holes GH (see FIGS. 10A and 10B).

As a result of performing the flattening process, the insulating spacer 124 and the inter-gate insulating film 132 may be consumed by a predetermined thickness from top surfaces thereof, and thus their thicknesses may be reduced in a Z direction, and the plurality of gate insulating films 118, the plurality of insulating spacers 124, and the inter-gate insulating film 132 may be exposed around top surfaces of the plurality of gate lines GL.

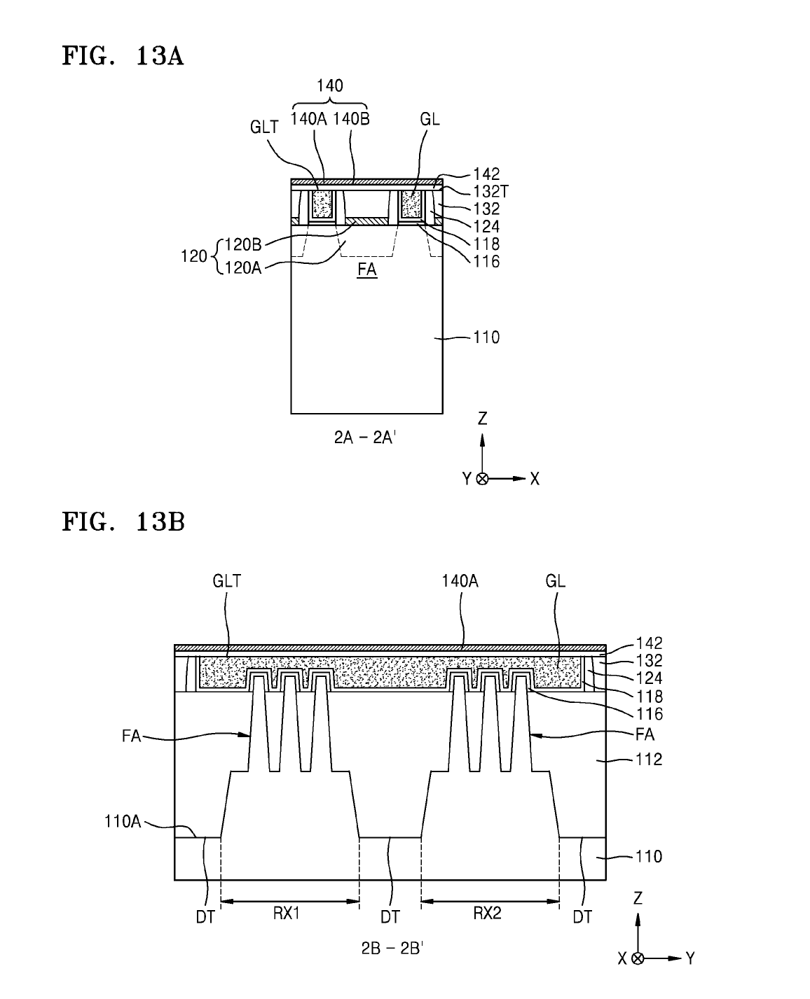

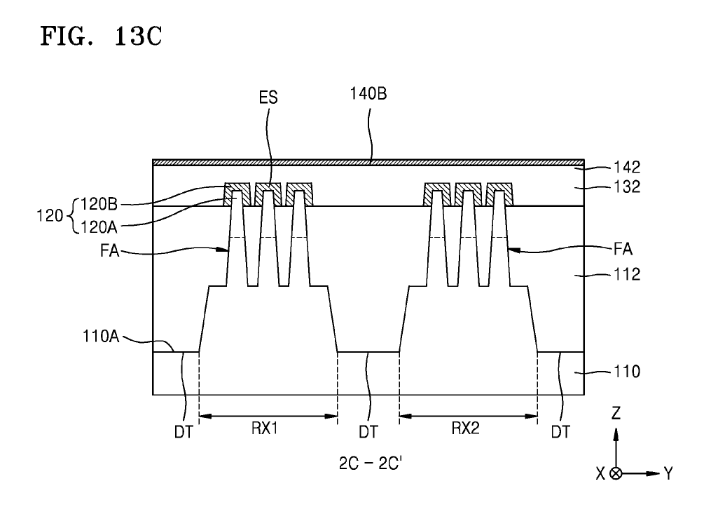

Referring to FIGS. 13A through 13C, the insulating margin layer 142 and the blocking insulating film 140 are sequentially formed on the gate line GL and the inter-gate insulating film 132. The blocking insulating film 140 may include the first part 140A covering the gate uppermost surface GLT of the gate line GL and the second part 140B integrally connected to the first part 140A and covering the inter-gate insulating film 132.

In some embodiments, to sequentially form the insulating margin layer 142 and the blocking insulating film 140, the insulating margin layer 142 may be formed by depositing a silicon oxide film having a thickness of about 50 Å, and then the blocking insulating film 140 may be formed by depositing a silicon nitride film having a thickness of about 50 Å on the insulating margin layer 142.

In some other embodiments, to sequentially form the insulating margin layer 142 and the blocking insulating film 140, a silicon oxide film having a thickness of about 100 Å may be deposited, and then a nitridation process may be performed until a predetermined thickness, for example, about 50 Å of the silicon oxide film from the top surface thereof is changed to a silicon nitride film. In this regard, the silicon nitride film obtained by performing the nitridation process may be configured as the blocking insulting film 140. A part of the silicon oxide film that is not nitrified may be configured as the insulating margin layer 142.

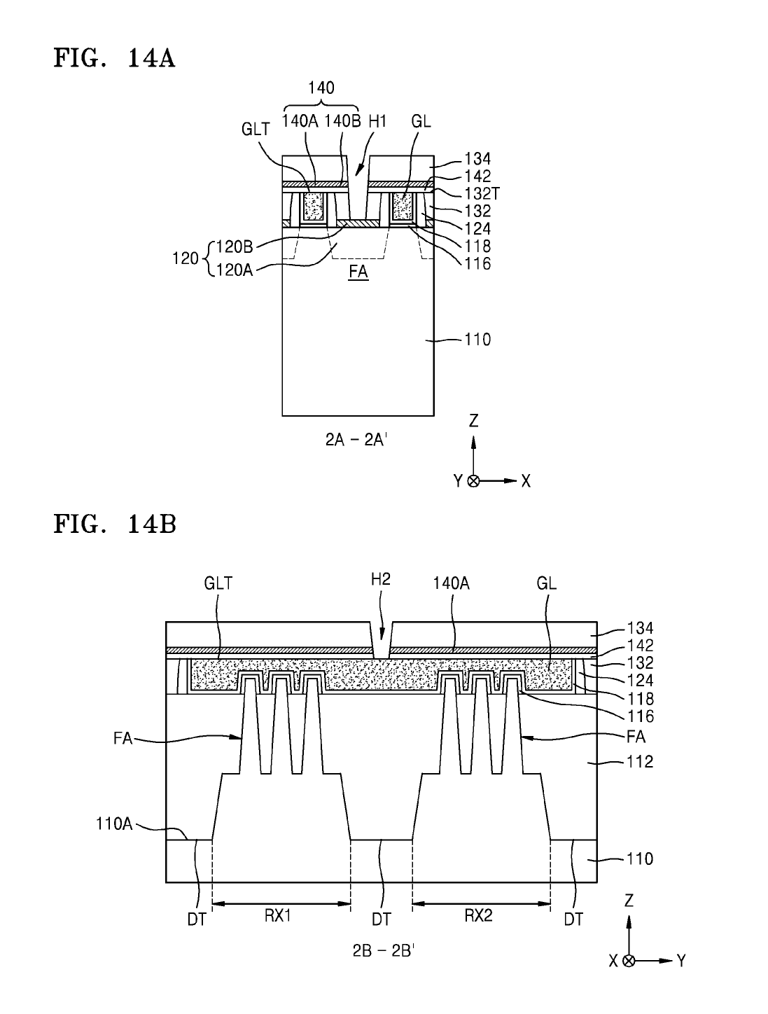

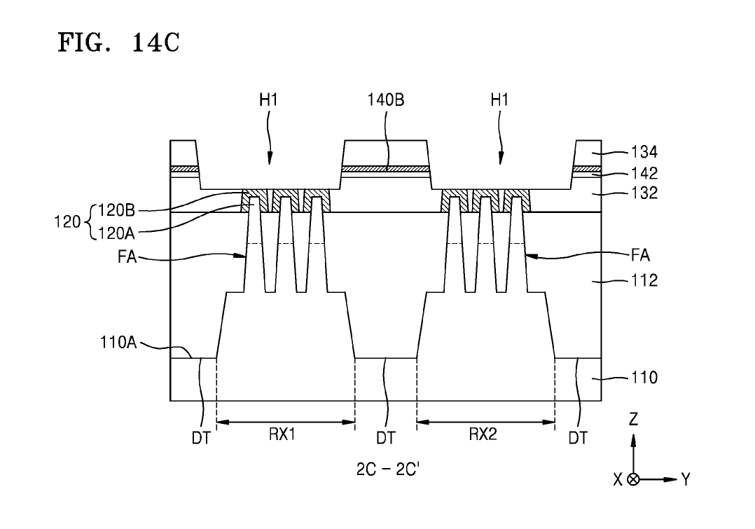

Referring to FIGS. 14A through 14C, the interlayer insulating film 134 is formed on the blocking insulating film 140, and then the first contact hole H1 exposing the source/drain region 120 and the second contact hole H2 exposing the gate line GL are formed.

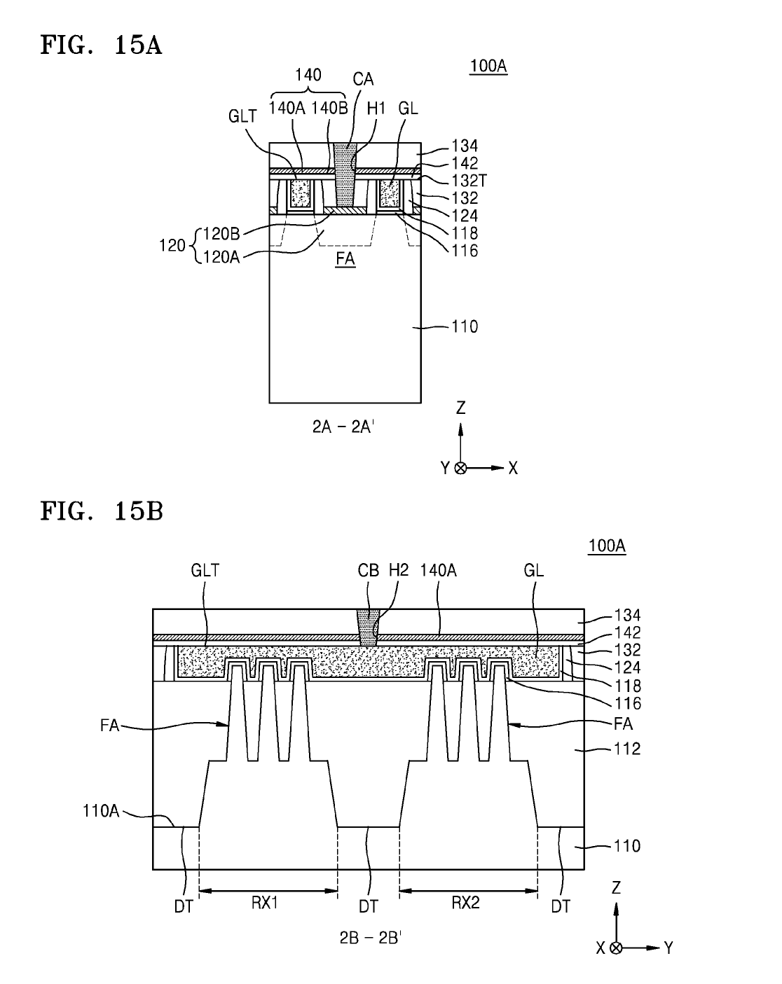

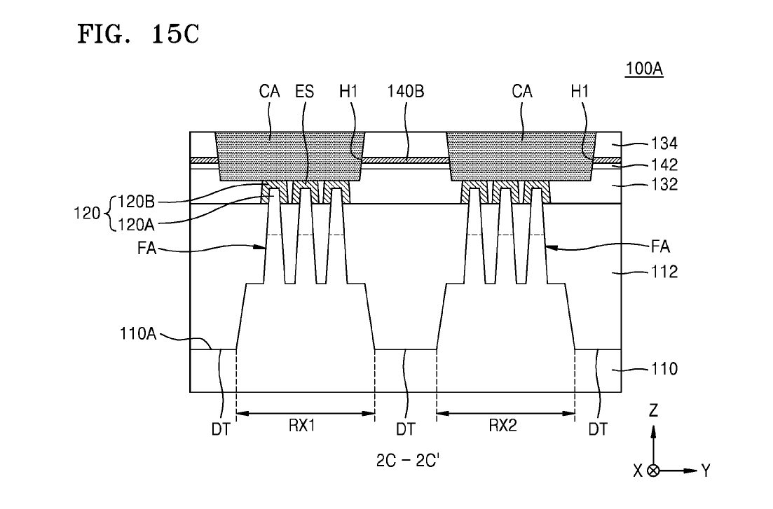

Referring to FIGS. 15A trough 15C, the first contact plug CA and second contact plugs CB, respectively, connected to the source/drain region 120 and the gate line GL are formed by filling the first contact hole H1 and the second contact hole H2 with a conductive material.

Although not shown, before the first contact plug CA is formed in the first contact hole H1, a metal silicide film may be formed on a surface of the source/drain region 120 exposed through the first contact hole H1, and then the first contact plug CA may be formed on the metal silicide film.

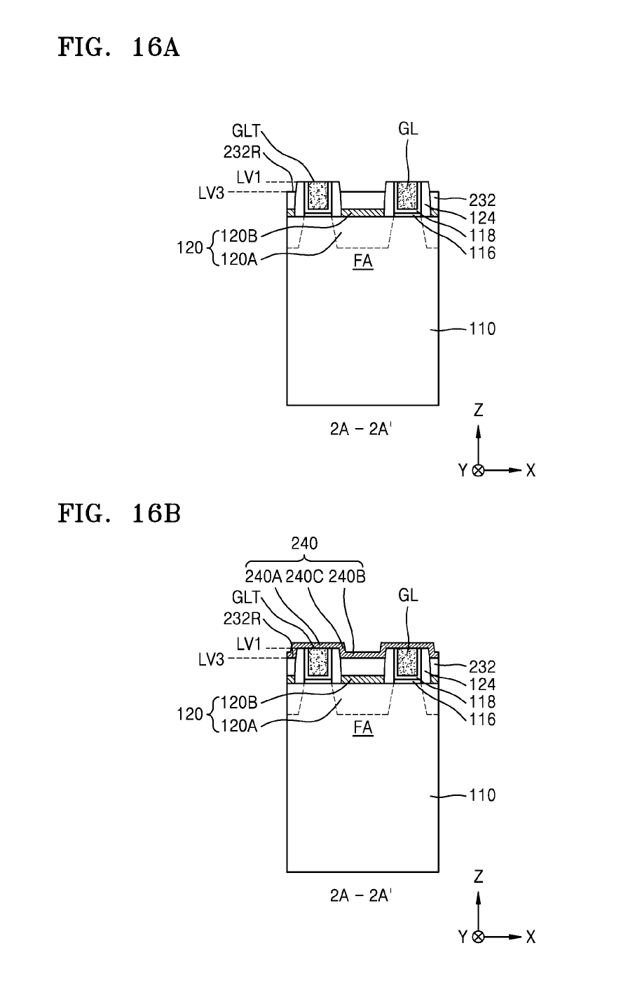

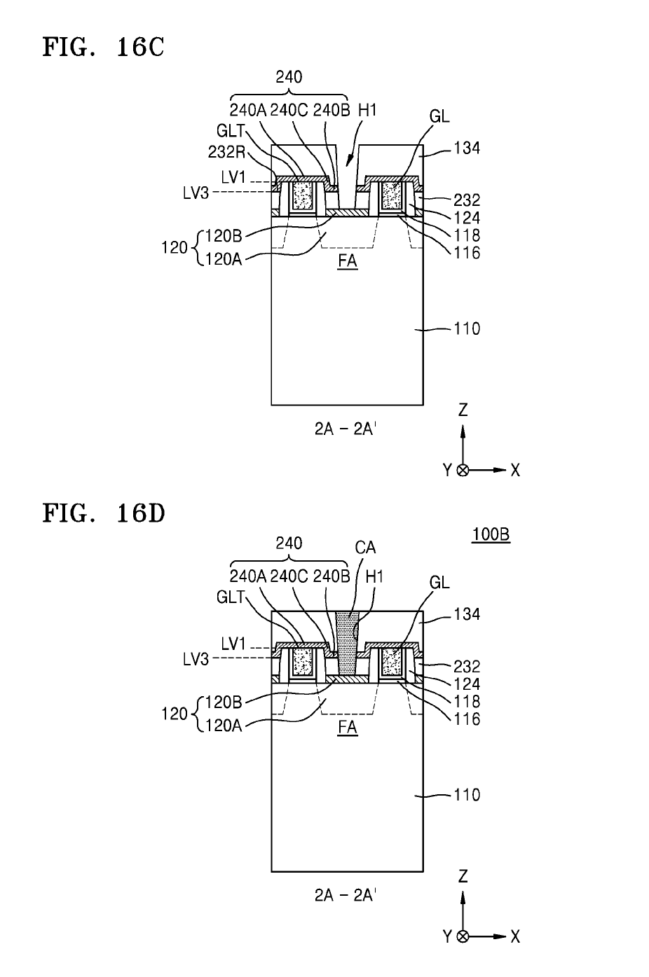

FIGS. 16A through 16D are cross-sectional views for sequentially explaining a method of manufacturing the integrated circuit device 100B of FIG. 3, according to another embodiment of the inventive concept. The method of manufacturing the integrated circuit device 100B of FIG. 3 will now be described with reference to FIGS. 16A through 16D. The same reference numerals between FIGS. 16A through 16D and FIGS. 1 through 15C denote the same elements, and thus detailed descriptions thereof are omitted here.

Referring to FIG. 16A, in the same manner as described with reference to FIGS. 6A through 12C above, the plurality of gate lines GL remaining only in the plurality of gate holes GH and the flattened inter-gate insulating film 132 are formed, and then the inter-gate insulating film 232 having a recess surface 232R is formed by selectively etching back the inter-gate insulating film 132.

The recess surface 232R of the inter-gate insulating film 232 may be disposed on the third level LV3 closer to the substrate 110 than the first level LV1 on the substrate 110 on which the gate uppermost surface GLT extends. The recess surface 232R of the inter-gate insulating film 232 may correspond to the insulating film uppermost surface 232T described with reference to FIG. 3.

In some embodiments, a process of selectively wet or dry etching the inter-gate insulating film 132 may be used to form the inter-gate insulating film 232 having the recess surface 232R by using an etching selectivity between the insulating spacer 124 and the inter-gate insulating film 132. For example, when the insulting spacer 124 is formed as a nitride film, and the inter-gate insulating film 132 is formed of an oxide film, the inter-gate insulating film 232 having the recess surface 232R may be formed by selectively etching the inter-gate insulating film 132 by using an etching atmosphere in which an oxide film may be selectively etched with a high etching selectivity with respect to the nitride film.

In some embodiments, the inter-gate insulating film 232 having the recess surface 232R may be formed such that a depth difference between the first level LV1 and the third level LV3 in a Z direction may be within the range of about 10˜about 150 Å, for example, about 30˜about 100 Å.

Referring to FIG. 16B, the inter-gate insulating film 232 having the recess surface 232R and the blocking insulating film 240 covering the gate line GL are formed.

The blocking insulating film 240 includes the first part 240A covering the gate line

GL, the second part 240B integrally connected to the first part 240A and covering the inter-gate insulating film 232, and the third part 240C covering side walls of the gate line GL.

The first part 240A of the blocking insulating film 240 may contact the gate uppermost surface GLT and extend at the first level LV1 on the substrate 110. The second part 240B of the blocking insulating film 240 may have a bottom surface extending at a third level LV3 closer to the substrate 110 than the first level LV1. The third part 240C of the blocking insulating film 240 may be integrally connected to the first part 240A and the second part 240B between the first part 240A and the second part 240B.

Referring to FIG. 16C, the interlayer insulating film 134 is formed on the blocking insulating film 240, and the first contact hole H1 exposing the source/drain region 120 is formed.

Referring to FIG. 16D, the first contact plug CA connected to the source/drain region 120 is formed by filling the first contact hole H1 with a conductive material.

Although not shown, before the first contact plug CA is formed in the first contact hole H1, a metal silicide film may be formed on a surface of the source/drain region 120 exposed through the first contact hole H1, and then the first contact plug CA may be formed on the metal silicide film.

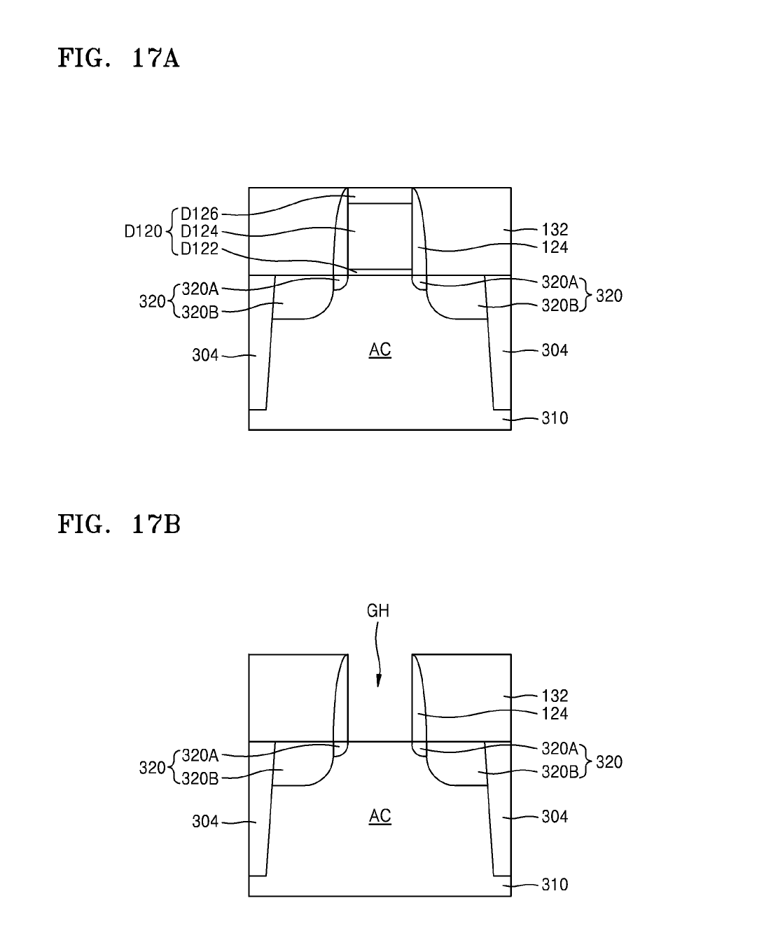

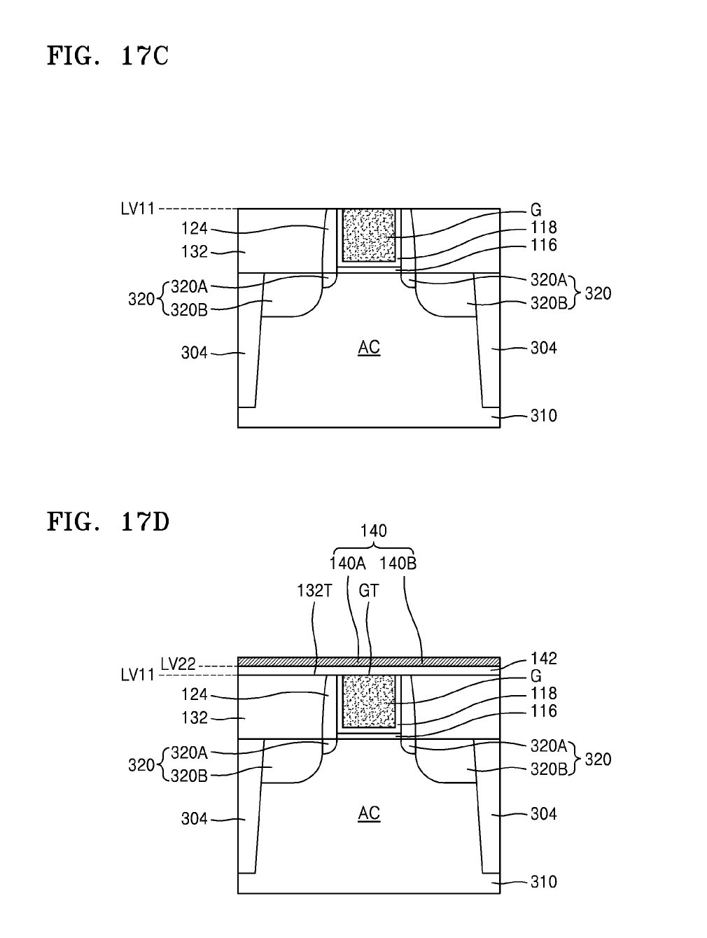

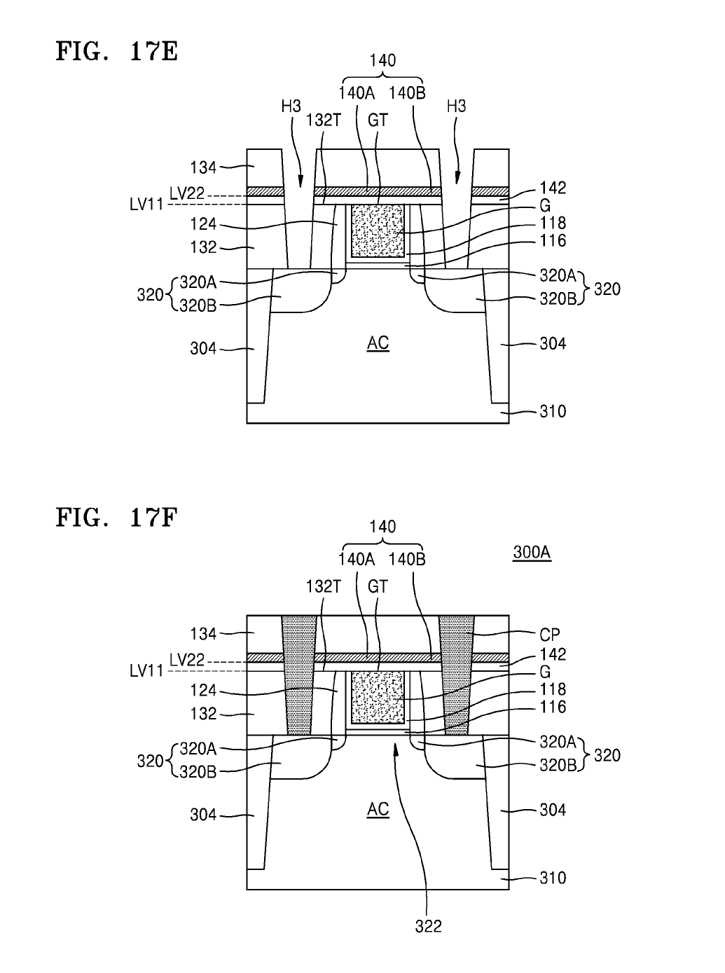

FIGS. 17A through 17F are cross-sectional views for sequentially explaining a method of manufacturing the integrated circuit device 300B, according to another embodiment of the inventive concept. The method of manufacturing the integrated circuit device 300B of FIG. 4 will now be described with reference to FIGS. 17A through 17F. The same reference numerals between FIGS. 17A through 17F and FIGS. 1 through 16D denote the same elements, and thus detailed descriptions thereof are omitted here.

Referring to FIG. 17A, the device isolation film 304 defining the active area AC is formed on the substrate 310.

The device isolation film 304 may be formed of a silicon oxide film, a silicon nitride film, or a combination of these.

Thereafter, in the same manner as described with reference to FIGS. 8A through 8C above, the dummy gate structure D120 is formed on the active area AC of the substrate 310.

The dummy gate structure D120 may include the dummy gate insulating film D122, the dummy gate electrode D124, and the dummy gate capping layer D126 that are sequentially stacked on the fin type active area FA. The dummy gate insulating film D122, the dummy gate electrode D124, and the dummy gate capping layer D126 are in more detail described with reference to FIGS. 8A through 8C above.

Thereafter, the source/drain extension regions 320A having a relatively small depth are formed in both sides of the dummy gate structure D120 by implanting dopants of a first doping concentration into the substrate 310 by using the dummy gate capping layer D126 as an ion implantation mask, The first doping concentration of the dopants may be determined in various ways according to a design of an integrated circuit device that is to be formed.

In some embodiments, before the implantation process for forming the source/drain extension region 320A, an oxide thin film may be formed to protect an exposed surface of the substrate 310. And, after the source/drain extension region 320A is formed, the oxide thin film may be removed through a wet etching process.

Thereafter, the insulating spacers 124 covering both sidewalls of the dummy gate structure D120 is formed, and then the deep source/drain regions 320B are formed in the substrate 310 in both sides of the dummy gate structure D120 by implanting dopants of a second doping concentration higher than the first doping concentration into the substrate 310 by using the dummy gate structure D120 and the insulting spacers 124 as an ion implantation mask. In some embodiments, the second doping concentration may be determined in various ways according to the design of the integrated circuit device that is to be formed.

The source/drain extension region 320A and the deep source/drain region 320B constitute the source/drain region 320.

In some embodiments, before an impurity ion implantation process for forming the deep source/drain region 320B is performed, the oxide thin film may be formed to protect the exposed surface of the substrate 310. And, after the deep source/drain region 320B is formed, the oxide thin film may be removed through a wet etching process.

Thereafter, the inter-gate insulating film 132 covering the source/drain region 320, the dummy gate structure D120, and the insulating spacer 124 is formed.

The inter-gate insulating film 132 having a flattened top surface may be formed by forming an insulating film having a thickness enough to cover the source/drain region 320, the plurality of dummy gate structures D120, and the insulating spacer 124, and flattening a resultant obtained by forming the insulating film is flattened such that the plurality of dummy gate structures D120 are exposed.

Referring to FIG. 17B, the gate hole GH is formed by removing the plurality of dummy gate structures D120 exposed through the inter-gate insulating film 132.

The insulating spacer 124 and the active area AC may be exposed through the plurality of gate holes GH.

Referring to FIG. 17C, in a similar manner as described with reference to FIGS. 11A through 12C, a flattening process is performed on a resultant of sequentially forming the interface film 116, the gate insulating film 118, and the gate G in the gate hole GH (see FIG. 17B) such that the gate G and the plurality of gate insulating films 118 may remain only in the gate hole GH (see FIG. 17B).

As a result of performing the flattening process, the insulating spacer 124 and the inter-gate insulating film 132 may be consumed by a predetermined thickness from top surfaces thereof, and thus their thicknesses may be reduced in a Z direction, and the gate insulating film 118, the insulating spacer 124, and the inter-gate insulating film 132 may be exposed around a top surface of the gate G.

The gate G may be formed to be disposed on the first level LV11 on the substrate 310.

Referring to FIG. 17D, in a similar way as described with reference to FIGS. 13A through 13C, the insulating margin layer 142 and the blocking insulating film 140 are sequentially formed on the gate G and the inter-gate insulating film 132. The blocking insulating film 140 may include the first part 140A covering the gate uppermost surface GT and the second part 140B integrally connected to the first part 140A and covering the inter-gate insulating film 132.

The blocking insulating film 140 may be formed such that bottom surfaces of the first part 140A and the second part 140B extend in parallel to the substrate 310 at the second level LV22 farther away from the substrate 310 than the first level LV11.

Referring to FIG. 17E, in a similar way as described with reference to FIGS. 14A through 14C, the interlayer insulating film 134 is formed on the blocking insulating film 140, and then a contact hole H3 exposing the source/drain region 320 is formed.

Referring to FIG. 17F, in a similar way as described with reference to FIGS. 15A through 15C, the conductive contact plug CP connected to the source/drain region 320 is formed by filling the contact hole H3 with a conductive material.

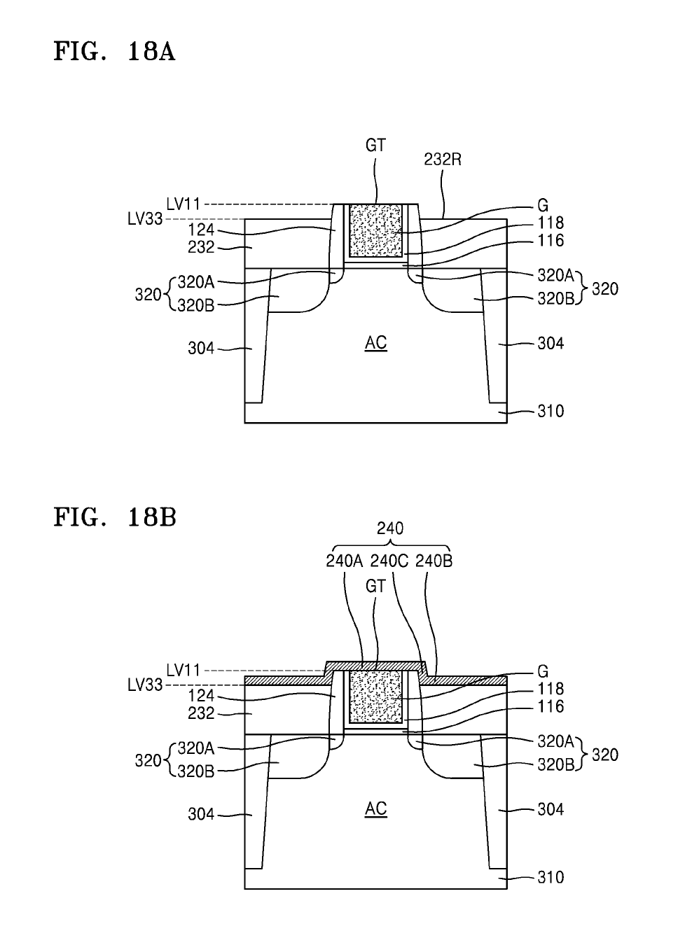

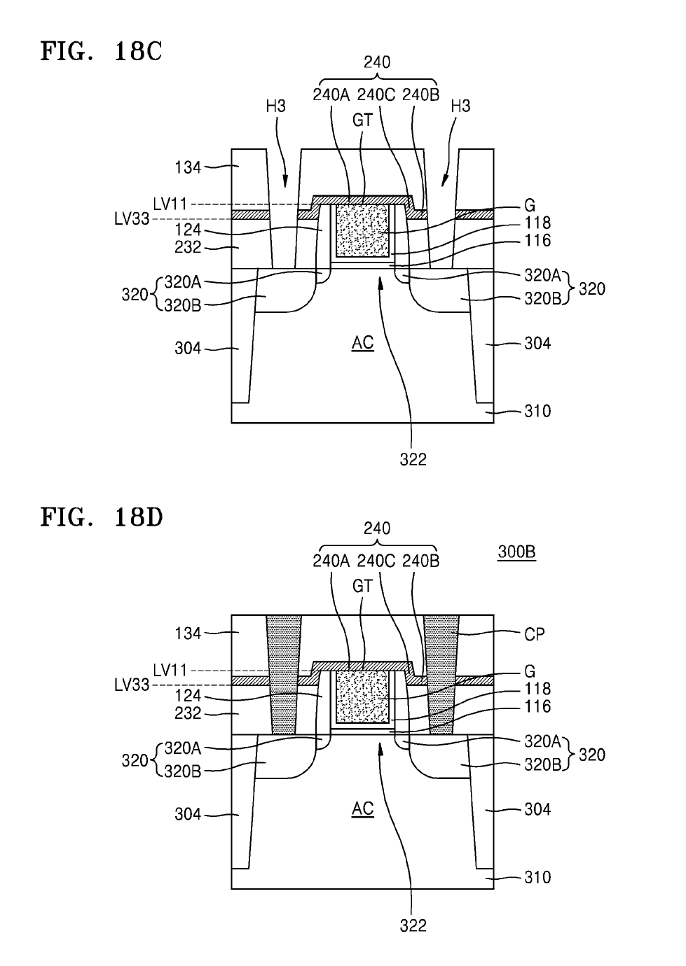

FIGS. 18A through 18D are cross-sectional views for sequentially explaining a method of manufacturing an integrated circuit device, according to another embodiment of the inventive concept. The method of manufacturing the integrated circuit device 300B of FIG. 5 will now be described with reference to FIGS. 18A through 18D. The same reference numerals between FIGS. 18A through 18D and FIGS. 1 through 17F denote the same elements, and thus detailed descriptions thereof are omitted here.

Referring to FIG. 18A, in a similar way as described with reference to FIGS. 17A through 17C, the gate G remaining only in the gate hole GH and the flattened inter-gate insulating film 132 are formed, and then the inter-gate insulating film 232 is formed by selectively etching back the inter-gate insulating film 132.

The recess surface 232R of the inter-gate insulating film 232 may be disposed on the third level LV33 closer to the substrate 110 than the first level LV11 on the substrate 110 on which the gate uppermost surface GT extends.

In some embodiments, the inter-gate insulating film 232 having the recess surface 232R may be formed such that a depth difference between the first level LV11 and the third level LV33 in a Z direction may be within the range of about 10˜about 150 Å, for example, about 30˜about 100 Å.

Referring to FIG. 18B, in a similar way as described with reference to FIG. 16B, the inter-gate insulating film 232 having the recess surface 232R and the blocking insulating film 240 covering the gate G are formed.

The blocking insulating film 240 includes the first part 240A covering the gate G, the second part 240B integrally connected to the first part 240A and covering the inter-gate insulating film 232, and the third part 240C covering side walls of the gate G.

The first part 240A of the blocking insulating film 240 may contact the gate uppermost surface GT and extend at the first level LV1 on the substrate 110. The second part 240B may have a bottom surface extending at the third level LV33 closer to the substrate 310 than the first level LV11. The third part 240C of the blocking insulating film 240 may be integrally connected to the first part 240A and the second part 240B between the first part 240A and the second part 240B.

Referring to FIG. 18C, in a similar way as described with reference to FIG. 16C or 17E, the interlayer insulating film 134 is formed on the blocking insulating film 240, and the contact hole H3 exposing the source/drain region 320 is formed.

Referring to FIG. 18D, the contact plug CA connected to the source/drain region 320 is formed by filling the contact hole H3 with a conductive material.

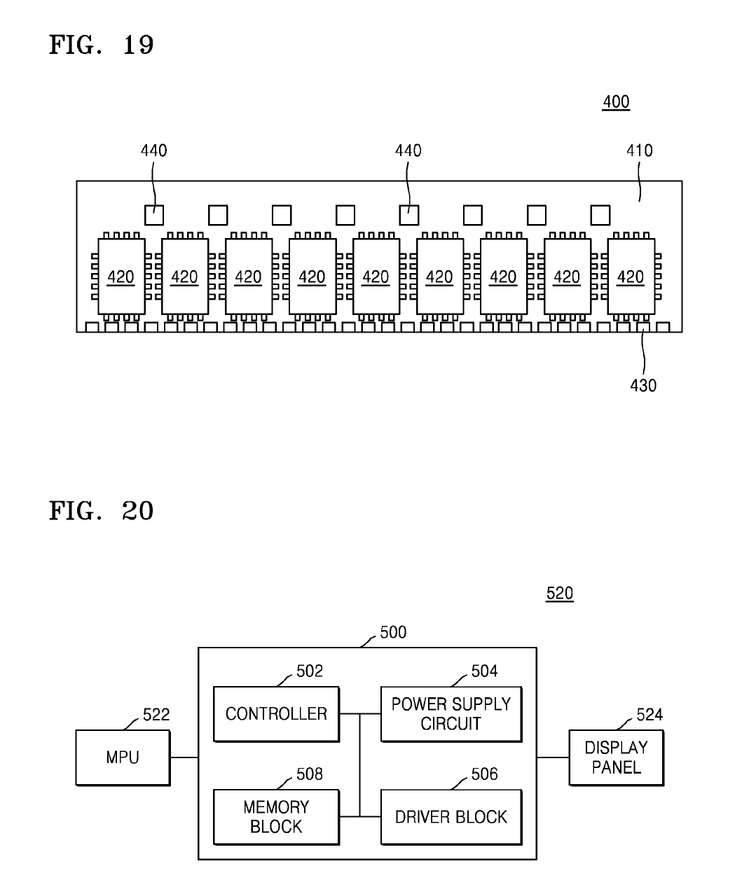

FIG. 19 is a plan view of a memory module 400, according to an embodiment of the inventive concept.

The memory module 400 includes a module substrate 410 and a plurality of semiconductor chips 420 attached to the module substrate 410.

The semiconductor chip 420 includes a semiconductor device according to an embodiment of the inventive concept. The semiconductor chip 420 includes at least one of the integrated circuit devices 100, 100A, 100B, 300A, and 300B.

A connection unit 430 that may be inserted into a socket of a mother board is disposed in one side of the module substrate 410. A ceramic decoupling capacitor 440 is disposed on the module substrate 410. The memory module 400 according to an embodiment of the inventive concept is not limited to the configuration of FIG. 19 but may be manufactured in various ways.

FIG. 20 is a schematic block diagram of a display driving integrated circuit (DDI) 500 and a display apparatus 520 including the DDI 500, according to an embodiment of the inventive concept.

Referring to FIG. 20, the DDI 500 may be an electronic device that includes a controller 502, a power supply circuit 504, a driver block 506, and a memory block 508. The controller 502 receives and decodes a command applied from a main processing unit (MPU) 522, and controls each block of the DDI 500 to implement an operation according to the command. The power supply circuit 504 drives a display panel 524 by using a driving voltage generated by the power supply circuit 504 in response to control of the controller 502. The display panel 524 may be a liquid crystal display panel or a plasma display panel. The memory block 508 that is a block temporally storing the command input to the controller 502 or control signals output from the controller 502 or storing necessary data may include a memory such as RAM, ROM, etc. At least one of the power supply circuit 504 and the driver block 506 includes at least one of the integrated circuit devices 100, 100A, 100B, 300A, and 300B of FIGS. 1 through 18D.

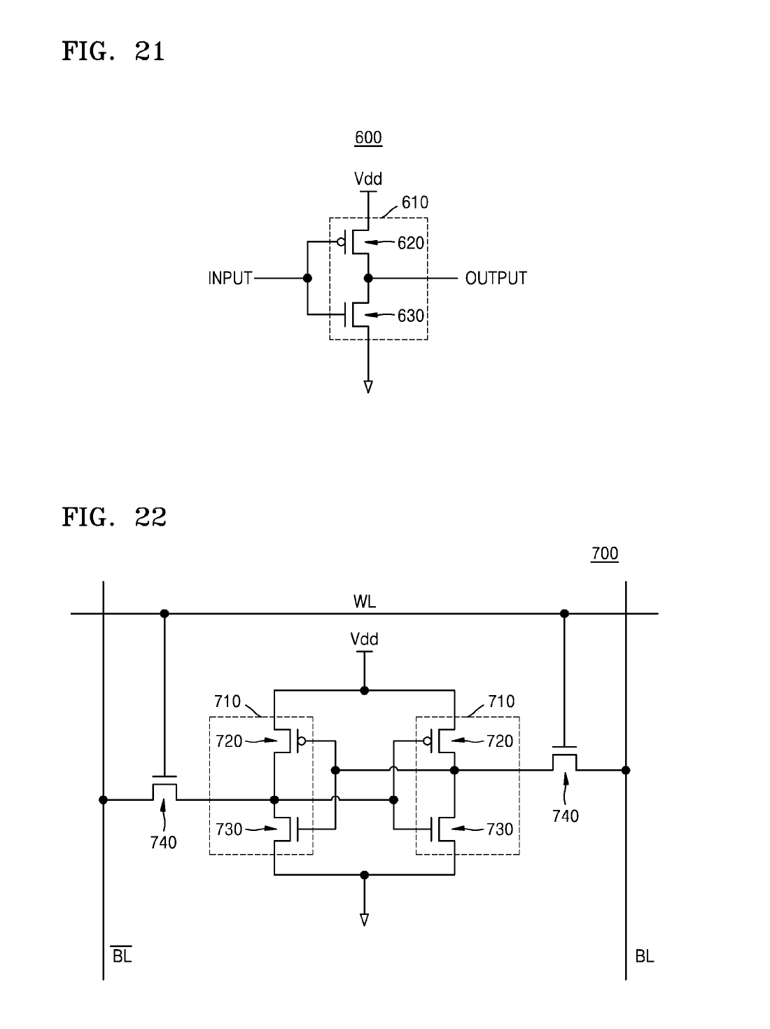

FIG. 21 is a circuit diagram of a CMOS inverter 600, according to an embodiment of the inventive concept.

The CMOS inverter 600 includes a COMS transistor 610. The CMOS transistor 610 includes a PMO transistor 620 and an NMOS transistor 630 that are connected between a power terminal Vdd and a ground terminal. The CMOS transistor 610 includes at least one of the integrated circuit devices 100, 100A, 100B, 300A, and 300B of FIGS. 1 through 18D.

FIG. 22 is a circuit diagram of a CMOS SRAM device 700, according to an embodiment of the inventive concept.

The CMOS SRAM device 700 includes a pair of driving transistors 710. Each of the pair of driving transistors 710 includes a PMO transistor 720 and an NMOS transistor 730 that are connected between the power terminal Vdd and a ground terminal. The CMOS SRAM device 700 further includes a pair of transmission transistors 740. A source of the transmission transistor 740 is cross-connected to a common node of the PMO transistor 720 and the NMOS transistor 730 included in the driving transistor 710. The power terminal Vdd is connected to a source of the PMOS transistor 720. The ground terminal is connected to a source of the NMOS transistor 730. A word line WL is connected to a gate of the pair of transmission transistor 740. A bit line BL and an inverted bit line are connected to drains of the pair of transmission transistor 740.

At least one of the driving transistors 710 and the transmission transistor 740 includes at least one of the integrated circuit devices 100, 100A, 100B, 300A, and 300B of FIGS. 1 through 18D.

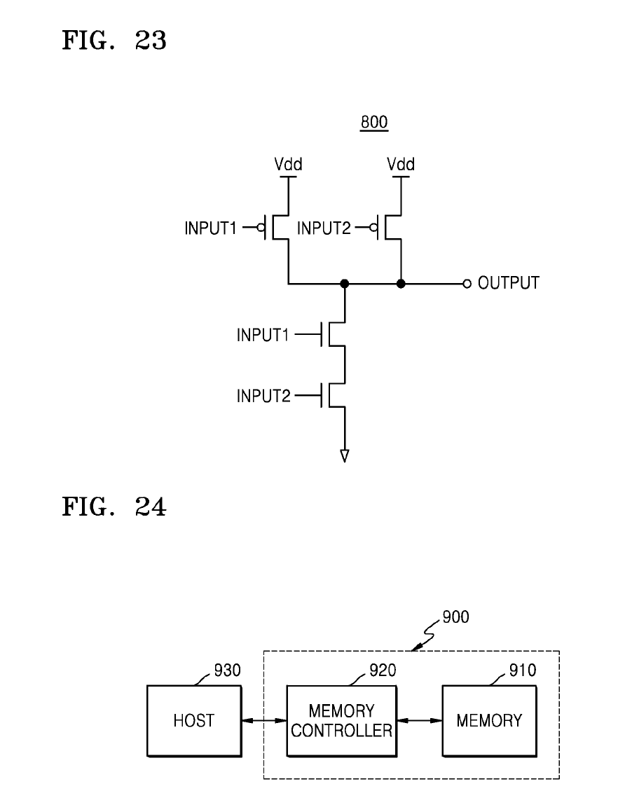

FIG. 23 is a circuit diagram of a CMOS NAND circuit 800, according to an embodiment of the inventive concept.

The CMOS NAND circuit 800 includes a pair of CMOS transistors to which different input signals are transmitted. The CMOS NAND circuit 800 includes at least one of the integrated circuit devices 100, 100A, 100B, 300A, and 300B of FIGS. 1 through 18D.

FIG. 24 is a block diagram of an electronic system 900, according to an embodiment of the inventive concept.

The electronic system 900 may be an electronic device that includes a memory 910 and a memory controller 920. The memory controller 920 controls the memory 910 to read data from the memory 910 and/or write the data to the memory 910 in response to a request of a host 930. At least one of the memory 910 and the memory controller 920 includes at least one of the integrated circuit devices 100, 100A, 100B, 300A, and 300B of FIGS. 1 through 18D.

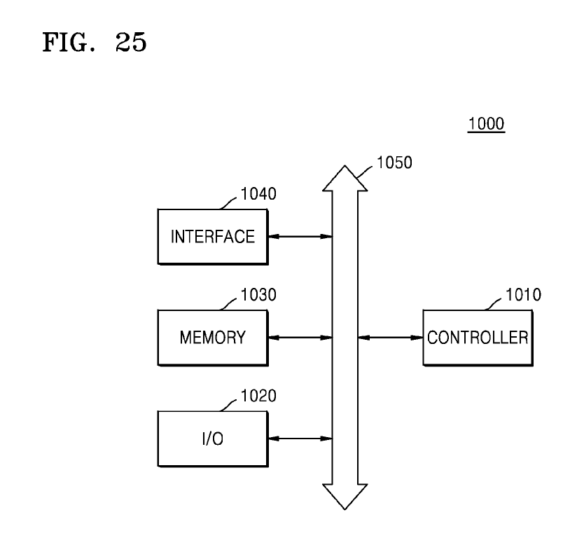

FIG. 25 is a block diagram of an electronic system 1000, according to another embodiment of the inventive concept.

The electronic system 1000 includes a controller 1010, an input/output device I/O 1020, a memory 1030, and an interface 1040, which are connected to each other via a bus 1050.

The controller 1010 may include at least one of a microprocessor, a digital signal processor, or a processing device similar to the microprocessor and the digital signal processor. The input/output device 1020 may include at least one of a keypad, a keyboard, and a display. The memory 1030 may be used to store a command executed by the controller 1010. For example, the memory 1030 may be used to store user data.

The electronic system 1000 may be configured as an electronic device such as a wireless communication device or a device capable of transmitting and/or receiving information in a wireless environment. The interface 1040 may be configured as a wireless interface to transmit and receive data over a wireless communication network in the electronic system 1000. The interface 1040 may include an antenna and/or a wireless transceiver. In some embodiments, the electronic system 1000 may be used in a communication interface protocol of a 3G communication system such as CDMA (code division multiple access), GSM (global system for mobile communications), NADC (North American digital cellular), E-TDMA (extended-time division multiple access), and/or WCDMA (wide band code division multiple access). The electronic system 1000 includes at least one of the integrated circuit devices 100, 100A, 100B, 300A, and 300B of FIGS. 1 through 18D.

While the inventive concept has been particularly shown and described with reference to exemplary embodiments thereof, it will be understood that various changes in form and details may be made therein without departing from the spirit and scope of the following claims.

What is claimed is:

1. An integrated circuit (IC) device comprising:
a fin type active area formed on a substrate;
a gate line extending in a direction across the fin type active area on the fin type active area and having a gate uppermost surface at a first level;
a pair of source/drain regions formed in the fin type active area at opposite sides of the gate line;
an inter-gate insulating film covering the pair of source/drain regions and both sidewalls of the gate line;
a blocking insulating film comprising a first part covering the gate uppermost surface and a second part integrally connected to the first part and covering the inter-gate insulating film at a level that is different from the first level; and
a contact plug penetrating the blocking insulating film and the inter-gate insulating film and connected to one of the pair of source/drain regions.

2. The IC device of claim 1, wherein the first part of the blocking insulating film is spaced apart from the gate uppermost surface, and
wherein the first part and the second part of the blocking insulating film extend in parallel to the substrate at a second level that is farther from the substrate than the first level.

3. The IC device of claim 1, further comprising; an insulating margin layer disposed between the gate line and the blocking insulating film and between the inter-gate insulating film and the blocking insulating film and surrounding the contact plug.

4. The IC device of claim 3, wherein the insulating margin layer comprises a same material as that of the inter-gate insulating film.

5. The IC device of claim 1, wherein the blocking insulating film comprises a top surface extending flat on a same plane from the first part to the second part.

6. The IC device of claim 1, wherein the inter-gate insulating film comprises an insulating film uppermost surface at a same level as the first level.

7. The IC device of claim 6, wherein the second part of the blocking insulating film is spaced apart from the insulating film uppermost surface of the inter-gate insulating film.

8. The IC device of claim 1, wherein the first part of the blocking insulating film contacts the gate uppermost surface,
wherein the second part of the blocking insulating film comprises a bottom surface extending at a third level closer to the substrate than the first level.

9. The IC device of claim 1, wherein the inter-gate insulating film comprises an insulting film uppermost surface at a fourth level closer to the substrate than the first level.

10. The IC device of claim 9, wherein the second part of the blocking insulating film contacts the insulating uppermost surface of the inter-gate insulating film.

11. The IC device of claim 1, further comprising: an insulating spacer covering sidewalls of the gate line,
wherein the blocking insulating film further comprises a third part covering the sidewalls of the gate line with the insulating spacer between the blocking insulating film and the third part.

12. An integrated circuit (IC) device comprising:
a gate formed on a substrate and comprising a gate uppermost surface at a first level;
a pair of source/drain regions formed in the substrate at opposite sides of the gate;
an inter-gate insulating film covering the pair of source/drain regions and both sidewalls of the gate;
a blocking insulating film comprising a first part covering the gate uppermost surface and a second part integrally connected to the first part and covering the inter-gate insulating film at a level that is different from the first level; and
a contact plug penetrating the blocking insulating film and the inter-gate insulating film and connected to one of the pair of source/drain regions.

13. The IC device of claim 12, wherein the first part of the blocking insulating film is spaced apart from the gate uppermost surface, and
wherein the first part and the second part of the blocking insulating film extend flat on a same plane.

14. The IC device of claim 12, further comprising; an insulating margin layer covering the gate and the inter-gate insulating film and formed of a material that is different from that of the blocking insulating film,
wherein the insulating margin layer covers sidewalls of the contact plug between the blocking insulating film and the inter-gate insulating film.

15. The IC device of claim 12, wherein the inter-gate insulating film comprises an insulating film uppermost surface at a fourth level that is closer to the substrate than the gate uppermost surface,
wherein the first part of the blocking insulating film contacts the gate uppermost surface; and
wherein the second part of the blocking insulating film contacts the insulating film uppermost surface.

16. An integrated circuit (IC) device comprising:
a pair of gates extending in parallel to each other with a first space therebetween on a substrate and each comprising a gate uppermost surface at a first level;
a source/drain region formed in the substrate between the pair of gates;
an inter-gate insulating film covering the source/drain region in the first space;
a blocking insulating film comprising a first part covering the pair of gates and a second part covering the inter-gate insulating film at a level that is different from the first level; and
a contact plug penetrating the blocking insulating film and the inter-gate insulating film and connected to the source/drain region.

17. The IC device of claim 16, further comprising; at least one fin type active area formed in the substrate,
wherein the pair of gates extend across the at least one fin type active area on the at least one fin type active area, and
wherein the source/drain region is formed in the at least one fin type active area.

18. The IC device of claim 16, wherein the pair of gates are formed of metal, and wherein the blocking insulating film comprises a film including silicon and nitrogen.

19. The IC device of claim 16, further comprising; an insulating margin layer disposed between the second part of the blocking insulating film and the inter-gate insulating film and formed of a material that is different from that of the blocking insulating film,
wherein the second part of the blocking insulating film is formed at a second level that is farther from the substrate than the first level.

20. The IC device of claim 16, wherein the first part of the blocking insulating film contacts the gate uppermost surface, and
wherein the second part of the blocking insulating film contacts the inter-gate insulating film at a third level closer to the substrate than the first level.
